(19) United States
(12) Patent Application Publication
(10) Pub. No.: US 2013/0034934 A1
(43) Pub. Date: Feb. 7, 2013

(54) WAFER LEVEL PACKAGE STRUCTURE AND METHOD FOR MANUFACTURING THE SAME

(71) Applicants: Koichi MEGURO, Setagaya (JP); Kanji Otsuka, Higashiyamato-shi (JP)

(72) Inventors: Koichi MEGURO, Setagaya (JP); Kanji Otsuka, Higashiyamato-shi (JP)

(73) Assignee: SK Link Co., Ltd., Kawasaki-shi (JP)

(21) Appl. No.: 13/418,134

(22) Filed: Mar. 12, 2012

(30) Foreign Application Priority Data
Mar. 14, 2011 (JP) 2011-056004

(51) Int. Cl. H01L 21/50; H01L 21/78

(52) U.S. Cl. 438/113; 438/460; 257/E21.599; 257/E21.499

(57) ABSTRACT

A method for manufacturing a wafer level package is provided that enables suppressing the wearing of a cutter and extending the lifetime of the cutter, including forming insulating first resin over the top face of a substrate, which includes a groove for wiring to be formed; forming a film of first metal that is to serve as a portion of the wiring on the top face of the first resin using physical vapor deposition; forming a film of second metal that is to form a portion of the wiring on the top face of the first metal, with a lower hardness than the first metal; setting a cutter at a height corresponding to a place where the film of the first metal is not formed on a side face of the groove or the film thickness is low; and cutting at least the first resin by scanning the cutter.

### CROSS-REFERENCE TO RELATED APPLICATIONS

This application is based upon and claims the benefit of priority from the prior Japanese Patent Application No. 2011-056004, filed on Mar. 14, 2011, the entire contents of which are incorporated herein by reference.

### BACKGROUND OF THE INVENTION

1. Field of the Invention

The present invention relates to a wafer level package structure and a method for manufacturing the same.

2. Background of the Invention

Recent years have seen a dramatic rise in demand for a reduction in the size of circuit systems using semiconductors. In order to meet such demand, there are cases where semiconductor circuits are implemented into a package (CSP) that has a size close to the chip size of the semiconductor circuits.

One known example of a method for realizing a CSP is a packaging method using a so-called wafer level package (WLP). As one example of a WLP, there is a method of forming external electrode and the like on a silicon wafer before it is cut into pieces through dicing, and the cutting thereof into pieces through dicing is performed after the external electrode and the like have been formed. When a WLP is employed, re-wiring patterns, external terminal electrode (second electrode), and the like can be formed on a large number of semiconductor chips at the same time, and thus the ability to increase productivity is expected. A WLP is therefore a semiconductor apparatus.

There is a fan-in type of WLP and a fan-out type of WLP. In the case of fan-in, an external electrode (external terminal) for a semiconductor apparatus is provided in a region whose size is equivalent to the chip size. For example, an external terminal is formed in the top face region of a chip via re-wiring and the like that have been formed on a passivation film on the chip. In the case of fan-out, an external terminal for a semiconductor apparatus is provided in a region whose size is larger than the chip size. For example, an external terminal is formed in the top face region of insulating resin in which a chip is embedded, via re-wiring and the like that have been formed on a passivation film on the chip. In the case of fan-out, multiple chips are embedded in insulating resin that has been formed on an insulating resin wafer, and re-wiring and an external electrode is formed on that insulating resin wafer. This enables raising productivity. Note that with a silicon wafer, after so-called wafer front-end processing (from circuit printing until when the passivation film is formed on the chip) has ended, dicing is performed to cut the wafer into function units, and the cut-up chips are mounted on the insulating resin wafer. A fan-out package is also a WLP.

Also, in recent years, LSI package processing has been integrated with wafer processing in order to achieve size reduction, cost reduction, and an improvement in functionality. However, re-wiring, insulating layers, and the like are formed on a wafer through a combination of methods such as PVD (Physical Vapor Deposition), plating, and photolithography, and there is demand for a further reduction in cost.

As a measure for achieving this, a technique has been proposed that employs a manufacturing method similar to damascene processing, in which an insulating material serving as permanent resist is subjected to unevenness processing using a method such as roll die pressing or photolithography, a metal layer is adhered onto the entire face thereof, and the projections in the permanent resist and the metal layer are polished, and thus the metal in the recessions in the permanent resist is patterned into wiring.

However, in the case where the polishing in this method is performed using a CMP (Chemical Mechanical Polishing) method that is employed in the wafer front-end processing, there is no cost-benefit over the combination of PVD, plating, and photolithography in conventional technology. Although a mechanical polishing method can be used in place of the CMP method, contamination by abrasives occurs, and more time is required for processing to keep a homogenous and flat working surface.

To address this, the cutting methods of Japanese Patent Laid-open Publication No. H7-326614 as first document, Japanese Patent Laid-open Publication No. 2004-319965 as second document, Japanese Patent Laid-open Publication No. 2005-64451 (U.S. Pat. No. 7,049,229 B2) as third document, Japanese Patent Laid-open Publication No. 2005-12098 as fourth document, and European patent application (unexamined application) No. EP 2075825 as fifth document have been proposed as low-cost techniques due to having a short cutting time and the ability to easily perform flattening processing. The documents 1 to 5 are hereby incorporated by reference.

At least one problem is that when the cutting methods used in Patent Documents 1 to 5 are used to form the metal in the recessions in the permanent resist into wiring, the fact that cutting is performed on a compound body including the permanent resist material and the metal leads to problems such as blade self-oscillation (chatter), blade wearing, and the adhesion of the cutting target to the blade unless careful consideration is given to the properties of the permanent resist material, the properties of the metal, the metal formation method, and the like, and productivity cannot be said to be good.

### SUMMARY

A representative configuration of a method for manufacturing a wafer level package according to the present invention includes: forming insulating first resin over a top face of a substrate, the first resin including a groove in which wiring is to be formed; forming a film of first metal that is to serve as a portion of the wiring on a top face of the first resin using physical vapor deposition; forming a film of second metal that is to form a portion of the wiring on a top face of the first metal, the second metal of a lower hardness than that of the first metal; setting a cutter at a height at which the film of the first metal is not formed on a side face of the groove, or setting a cutter at a height corresponding to a place where the thickness of the film of the first metal formed on the side face of the groove is lower than the thickness of the film of the first metal formed on an upper face of the first resin or lower than the thickness of the film of the first metal formed on a bottom face of the groove, or setting a cutter at a height corresponding to a low-thickness portion of the first metal whose film thickness varies on the side face of the groove, the low-thickness portion having a thickness lower than the thickness of the film of the first metal formed on an upper face of the first resin or than the thickness of the film of the first metal formed on a bottom face of the groove; and cutting at least the first resin by scanning the cutter.

According to this configuration, for example, as a result of the first film formation step, a film of the first metal of a relatively high hardness is formed from the upper face of the first resin to the upper portion of the side faces of the groove. However, the film thickness of the first metal formed on the side faces of groove gradually decreases when moving farther downward (toward the bottom of the groove), and eventually reaches zero. Next, when forming a film of second metal, a film of the second metal is formed on the film of the first metal formed on the bottom portion of the groove, the upper face of the first resin, and the upper portion of the side faces of the groove.

A feature of the present invention is that, after the above-described film formation is performed, cutting is performed by the cutter along a cutting line at a height at which the film of the first metal is not formed on the side faces of the groove (a thickness of zero), for example. Accordingly, only two types of material are cut by the cutter, namely the first resin that is the softest among the cutting targets, and the second metal whose hardness is relatively lower than that of the first metal, for example.

In the case where the cutter cuts the first resin at a height close to the upper face thereof, a film of the first metal, which is a relatively higher hardness than the second metal, is formed with a substantial thickness also on part of the side faces of the groove. Accordingly, three types of material, further including the first metal, are cut. When compared with this case, in the present invention (cutting is performed at a height at which the film of the first metal is not formed (a thickness of zero), the extent of wearing of the cutter is very low, and the lifetime of the cutter can be significantly extended. Also, the present invention has a remarkable effect of preventing distortion of the wiring pattern for the metal that is to form wiring.

On the other hand, in the present invention as well, in the case where cutting by the cutter is performed at a height where the thickness of the first metal is low, three types of materials, including the first metal, are cut. However, a feature of the present invention is that cutting by the cutter is performed at a height corresponding to a place where the thickness of the film of the first metal formed on the side faces of the groove is lower than the thickness of the film of the first metal formed on the upper face of the first resin, or lower than the thickness of the film of the first metal formed on the bottom face of the groove. Accordingly, compared to the case of cutting at a height where the thickness of the film of the first metal formed on the side faces of the groove is high, the extent of wearing of the cutter is lower, and the lifetime of the cutter can be extended.

A main component of the first resin may be phenol resin, unsaturated polyester resin, melamine resin, or urea resin. For example, in the case of cutting using a cutter such as a bit (beitel) or a cutting tool made of diamond, it is desirable to use a thermoset resin that does not undergo plastic deformation due to local heat generation during cutting. This is because it is thought that it is favorable for the first resin to be a resin that has appropriate elasticity and low tensile strength with respect to the stress-distortion curve, in order to improve the cutting by the cutter. This is because, for example, it is preferable that the first resin is a resin with a distortion percentage due to stress of several percent or lower, and such a resin is a material that does not tend to undergo crazing and has a low amount of sticking to the cutter. All of the above-described resins contain it-shaped cyclic groups that are hard and undergo little stretching, with an elasticity of 2 to 4 GPa, for example.

Also, since these resins have the properties of being hard and stretching little, when these resins are cut, a gap does not tend to be formed between them and the adjacent metal that is cut at the same time. This has a remarkable effect of preventing distortion of the metal that forms wiring due to the distortion of the resin.

The substrate may have a passivation film on at least a portion of the top face thereof, and the passivation film may be in contact with the first resin. Due to the passivation film and the first resin being in contact with each other, the adhesion (adhesive force) of the first resin is improved, and cutting performance is further improved.

A main component of the passivation film may be polyimide resin. This is because phenol resin, unsaturated polyester resin, melamine resin, and urea resin, one of which is used as the first resin in contact with the passivation film, are all photosensitive resin that adheres to polyimide resin, and have a high adhesive force and are easily cut.

The film of first metal may be formed using an ion plating method that employs a metal mask including an opening portion at a position corresponding to the groove.

According to this configuration, a film of the first metal is formed on the metal mask and in the groove as a result of forming the film of first metal. After the metal mask is lifted off, a film of the second metal is formed on the film of the first metal that was formed in the groove, and only a film of the second metal is formed directly on the upper face of the first resin and the side faces of the groove. Accordingly, cutting can be performed along the cutting line where the first metal is not present or where the thickness of the first metal is low, without concern being given to the film thickness of the first metal on the side faces of the groove.

The film of second metal may be formed using physical vapor deposition, or may be performed using an ion plating method that employs a metal mask including an opening portion at a position corresponding to the groove.

According to this configuration, films of the first and second metal are formed on the metal mask and in the groove as a result of forming a film of first metal and of forming a film of second metal. Next, when the metal mask is lifted off, films of the first and second metal are formed only in the groove. Accordingly, in this case as well, cutting can be performed along the cutting line where the first metal is not present or where the thickness of the first metal is low, without concern being given to the film thickness of the first metal on the side faces of the groove.

On the other hand, the film of second metal may be formed using a sputtering method. This is because there is little influence on the wearing of the cutter and the like even when the film thickness of the second metal, which has a relatively lower hardness than that of the first metal, is higher than the thickness of a film of the second metal formed using an ion plating method.

The film of second metal may be formed using a plating method instead of a physical vapor deposition method such as ion plating or sputtering. This is because there is little influence on the wearing of the cutter and the like even when the film thickness of the second metal, which has a relatively lower hardness than that of the first metal, is higher than the thickness of a film of the second metal formed using physical vapor deposition.

In the step of forming the insulating first resin, the first resin may be formed such that a cross section of the first resin adjacent to the groove is rectangular or positive tapered with respect to the top face of the substrate.

Even if the first resin that is adjacent to the groove has a positive tapered cross section, the thickness of the film of the first metal that is formed gradually decreases when moving downward (toward the bottom of the groove) along the side faces of the groove, and becomes less than the thickness of the film of the first metal formed on the upper face of the first resin, for example.

Also, if the cross section of the first resin adjacent to the groove is rectangular, the side faces of the groove are perpendicular faces. Accordingly, as previously described, the film thickness of the first metal gradually decreases when moving downward along the side faces of the groove and eventually reaches zero, thus enabling realizing a structure to which the cutting of the present embodiment can be applied.

The width of the opening portion may be less than the width of the groove. This is because this configuration enables intentionally further reducing the film thickness of the first metal on the side faces of the groove.

In the step of forming the insulating first resin, the first resin may be formed such that a cross section of the first resin adjacent to the groove is inverse tapered with respect to the top face of the substrate.

If the first resin has this inverse tapered cross section, the side faces of the groove are inclined faces such that the first resin becomes narrower toward the bottom. Accordingly, the film thickness of the first metal on the side faces of the groove is even lower than the film thickness of the first metal in the case where the first resin has a rectangular cross section. Accordingly, the thickness of the first metal on the side faces of the groove is even lower. Therefore, for example, there is a wider range (margin) in which the cutting can be performed, in which the cutter is set to a height at which the thickness of the first metal is zero.

A feature of this configuration is that by intentionally further reducing the film thickness of the first metal on the side faces of the groove in this way, there is a wider range (margin) in which the cutting of the present invention can be performed, that is to say, in which the thickness of the first metal is low.

When the cross section of the first resin is the inverse tapered shape as described above, the film of first metal may be formed using a sputtering method. This is because, for example, due to the cross section of the first resin of an inverse tapered shape, the film thickness of the first metal on the side faces of the groove are equivalent to the film thickness obtained when using an ion plating method.

When the cross section of the first resin is the inverse tapered shape as described above, the film of second metal may be formed using an ion plating method or may be performed using a sputtering method. It is often the case that with an ion plating method, a greater film thickness of metal can be obtained per predetermined amount of time than with a sputter method, and cost is reduced. On the other hand, in the case of manufacturing the wafer level package of the present invention with a manufacturing line with a mixture of products including sputtering devices, it is possible to, for example, apply the sputtering method to the first and second film formation if the first resin is inverse tapered. This enables suppressing equipment investment for new ion plating devices. This is because the film thickness of the second metal, which has a relatively lower hardness than that of the first metal, has little influence on the wearing of the cutter and the like.

The substrate may be a semiconductor substrate including a circuit and an internal terminal electrode for input and output of a signal with the circuit, and the film of the first metal and the film of the second metal formed in the groove may form a wiring layer that is connected to the internal terminal electrode and an external terminal electrode provided as a fan-in in a region corresponding to a chip of the semiconductor substrate.

The substrate may include a semiconductor chip in which a circuit and an internal terminal electrode for input and output of a signal with the circuit are included, and insulating second resin that covers at least a side face of the semiconductor chip, and the film of the first metal and the film of the second metal formed in the groove may form a wiring layer that is connected to the internal terminal electrode and an external terminal electrode provided as a fan-out in the second resin outside a region of the semiconductor chip.

For example, the above-described substrate is a fan-out WLP substrate in which a plurality of chips obtained by dicing a wafer are re-aligned on the second resin.

The present invention enables providing a method for manufacturing a wafer level package that enables suppressing the wearing of a cutter and extending the lifetime of the cutter. Also, the present invention prevents distortion of the wiring pattern for the metal that is to form wiring, and thus has a remarkable effect of making it possible to realize fine pattern processing while being inexpensive.

### BRIEF DESCRIPTION OF THE DRAWINGS

Embodiments of the invention will be described, by way of example only, with reference to the drawings.

FIG. 1 is a schematic cross-sectional diagram illustrating the structure of a circuit board (silicon wafer) according to preferred embodiments of the present invention.

FIG. 2 is a plan view of an assembled package according to the present invention as viewed from the ball side.

FIG. 3 is a side view of the assembled package according to the present invention.

FIG. 4 is a plan view of a re-wiring portion for describing a WLP manufacturing method according to the present invention.

FIG. 5 is a cross-sectional diagram for describing a first embodiment of the WLP manufacturing method according to the present invention.

FIG. 6 is a cross-sectional diagram for describing the WLP manufacturing method according to the present invention.

FIG. 7 is a cross-sectional diagram for describing the WLP manufacturing method according to the present invention.

FIG. 8 is a cross-sectional diagram for describing the WLP manufacturing method according to the present invention.

FIG. 9 is a cross-sectional diagram for describing the WLP manufacturing method according to the present invention.

FIG. 10 is a cross-sectional diagram for describing the WLP manufacturing method according to the present invention.

FIG. 11 is a cross-sectional view of a wiring layer 21 of the WLP according to the present invention.

FIG. 12 is a cross-sectional diagram for describing the WLP manufacturing method according to the present invention.

FIG. 13 is a cross-sectional diagram for describing the WLP manufacturing method according to the present invention.

FIG. 14 is a cross-sectional diagram for describing the WLP manufacturing method according to the present invention.

FIG. 15 is a cross-sectional diagram for describing the WLP manufacturing method according to the present invention.

FIG. 16 is a cross-sectional diagram for describing the WLP manufacturing method according to the present invention.

FIG. 17 is a flowchart illustrating a process flow that is common to second to seventh embodiments of the WLP manufacturing method according to the present invention.

FIGS. 18A to 18D are schematic diagrams illustrating an example of changes in a WLP manufactured according to the flowchart of FIG. 17.

FIG. 19 is a diagram illustrating the second embodiment of the WLP manufacturing method according to the present invention.

FIG. 20 is a diagram illustrating an intermediate wafer level package obtained as a result of completion of the WLP manufacturing method in FIG. 19.

FIG. 21 is a table showing physical properties of various types of resin and metal used in embodiments of the present invention.

FIG. 22 is a schematic diagram illustrating an example of crazing that appears in resin (polyimide resin or the like) that is not suitable as the first resin in FIG. 19.

FIGS. 23A and 23B are graphs showing stress-distortion curves for various types of resin.

FIGS. 24A and 24B are schematic diagrams microscopically illustrating cutting at a height H0 in FIG. 19.

FIG. 25 is a diagram illustrating the third embodiment of the WLP manufacturing method according to the present invention.

FIG. 26 is a diagram illustrating an intermediate wafer level package obtained as a result of completion of the WLP manufacturing method in FIG. 25.

FIG. 27 is a diagram illustrating the fourth embodiment of the WLP manufacturing method according to the present invention.

FIG. 28 is a diagram illustrating an intermediate WLP obtained as a result of completion of the WLP manufacturing method in FIG. 27.

FIG. 29 is a diagram illustrating the fifth embodiment of the WLP manufacturing method according to the present invention.

FIG. 30 is a diagram showing the result of film formation in which the step of forming a film of second metal was performed after the metal mask was lifted off from the film formation state in FIG. 29.

FIG. 31 is a diagram showing an intermediate WLP that is obtained as a result of performing the cutting and flattening step from the film formation state in FIG. 30.

FIG. 32 is a diagram illustrating the sixth embodiment of the WLP manufacturing method according to the present invention.

FIG. 33 is a diagram illustrating the seventh embodiment of the WLP manufacturing method according to the present invention, and is a plan view of the substrate used in this embodiment.

FIGS. 34A and 34B are cross-sectional views of FIG. 33.

FIGS. 35A to 35D are diagrams illustrating an example of steps for manufacturing the fan-out WLP substrate in FIG. 33.

FIG. 36 is a diagram illustrating an example of a completed WLP that was manufactured by applying the WLP manufacturing method shown in FIG. 17 to the fan-out WLP substrate in FIG. 33.

### DETAILED DESCRIPTION OF THE INVENTION

Below is a detailed description of preferred embodiments of the present invention with reference to the attached drawings.

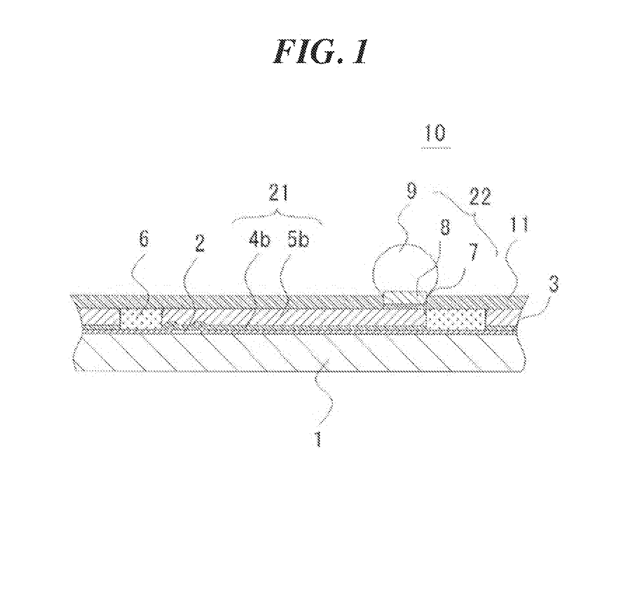

FIG. 1 is a schematic cross-sectional diagram illustrating the structure of a circuit board (including a silicon wafer) according to preferred embodiments of the present invention.

As shown in FIG. 1, a silicon wafer 10 according to the embodiments of the present invention includes a substrate 1 serving as the wafer main body, chip lead-out electrodes (internal terminal electrodes) 2 formed over the top face of the substrate 1, and solder balls (external terminal electrodes) 9 that are electrically connected to the chip lead-out electrodes 2. The substrate 1 is a collective substrate made up of multiple semiconductor chips that are separated at a later time. The circuits formed on the semiconductor chips are all the same.

Substantially the entire top face of the substrate 1 other than the regions where the chip lead-out electrodes 2 are provided is covered by an insulating passivation film 3. The chip lead-out electrodes 2 are made of aluminum (Al) for example, but there is no particular limitation to this. The top face of the chip lead-out electrodes 2 that is in contact with later-described wiring layers may have been plated (with Ni+Au, for example) in advance. Note that there are cases where “substrate 1” as used in this specification includes the chip lead-out electrodes 2 and the passivation film 3. Accordingly, there are cases where “the top face of the substrate 1” refers to the top face of the chip lead-out electrodes 2 and the top face of the passivation film 3 as well.

The portion made up of the substrate 1, the chip lead-out electrodes 2, and the passivation film 3 is a portion that is manufactured in so-called front-end processing (diffusion processing). In the front-end processing, ultrafine internal wiring and the like that is related to a circuit is formed on a substrate using an extremely high-precision photolithography method that employs a stepper or the like. The chip lead-out electrodes 2 are the portions serving as terminals for this internal wiring. The top face of the silicon wafer 10 of the embodiments of the present invention is subjected to processing at the wafer level in order to form wiring layers 21 and 22, the solder balls 9, and the like shown in FIG. 1. Note that the external terminal electrodes are not limited to being the solder balls 9 in the present invention. Resin 6, which is a feature of the present invention, establishes electrical insulation between the wiring layer 21 (first metal wiring) and the wiring layer 21 (second metal wiring that is physically adjacent to the first wiring).

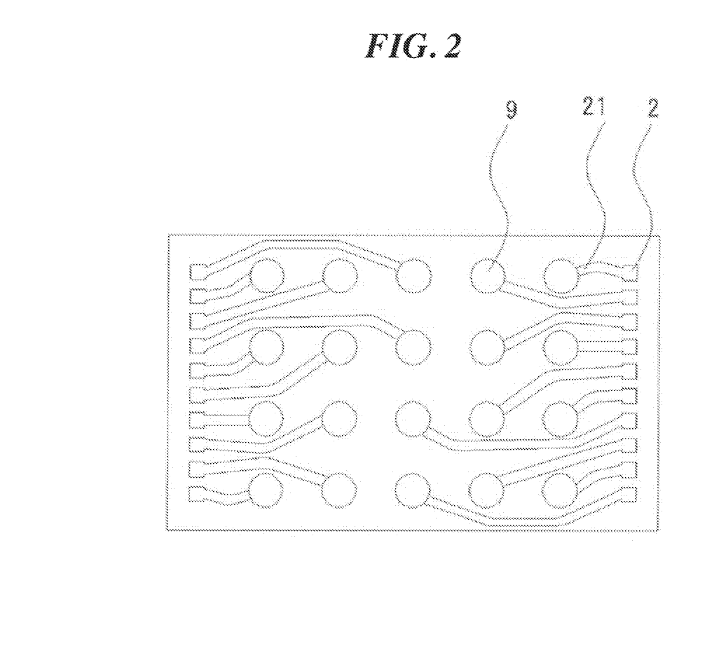

FIG. 2 is a plan view of an assembled package according to the present invention. In FIG. 2, the face on which the solder balls 9 are formed is the top face.

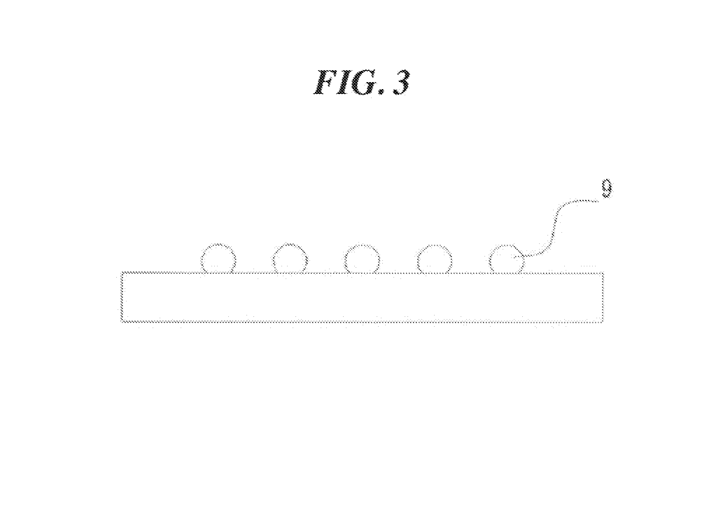

FIG. 3 is a side view of the assembled package according to the present invention. In FIG. 3, the face on which the solder balls 9 are formed is the upper face.

As shown in FIG. 1, the chip lead-out electrodes 2 and the passivation film 3 are provided on the top face of the substrate 1. As described above, the passivation film 3 covers substantially the entire top face of the substrate 1 other than the regions where the chip lead-out electrodes 2 are provided. The lead-out electrodes 2 are connected to the wiring layer 21, which is a laminate layer including barrier metal wiring 4b and aluminum wiring 5b. It is sufficient for the barrier metal wiring 4b to have a thickness of approximately 0.3 μm and for the aluminum wiring 5b to have a thickness of approximately 5 μm, but there is no particular limitation to this.

Note that the material of the wiring 5b may be copper (Cu), and in the case of forming a wiring layer from copper (Cu), copper (Cu) can be laminated on the barrier metal using a plating method.

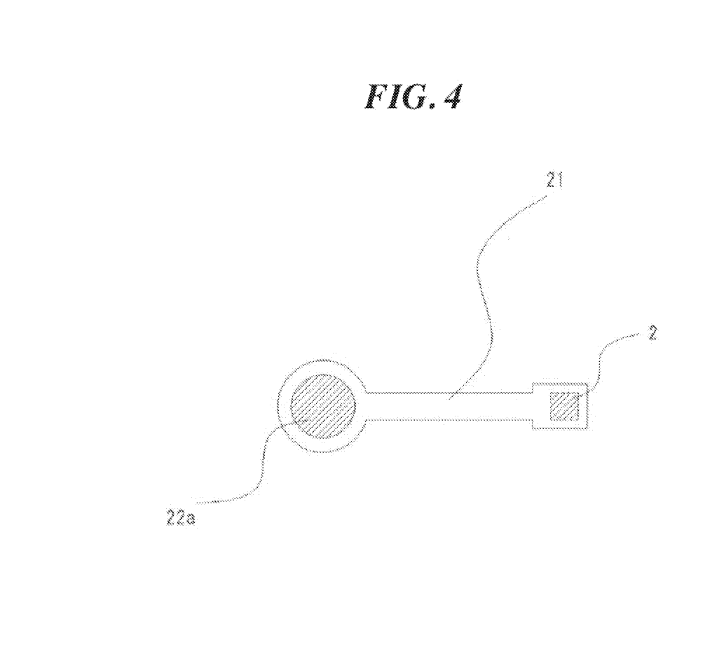

FIG. 4 shows an example of the planar shape of the wiring layer 21, and a protective insulating film 11 (FIG. 1) covers the entirety of the upper face of the wiring layer 21 other than a portion 22a that is covered by the wiring layer 22, but there is no particular limitation to this. In this specification, the portion of the upper face of the wiring layers 21 and 22 that is not covered by the protective insulating film 11 is sometimes referred to as the “first portion”, and the portion covered by the protective insulating film 11 is sometimes referred to as the “second portion”. Accordingly, the wiring layer 21 does not include the first portion.

Furthermore, as shown in FIG. 1, an end portion of the wiring layer 21 is connected to the second wiring layer 22 that is a laminate layer including barrier metal wiring 7 and copper wiring 8. It is sufficient for the barrier metal wiring 7 to have a thickness of approximately 0.3 μm and for the copper wiring 8 to have a thickness of approximately 10 μm, but there is no particular limitation to this. The copper wiring 8 may be aluminum wiring instead. The second wiring layer 22 is a wiring layer that functions as a post electrode for grounding the solder balls 9, and is provided perpendicular to the top face of the substrate 1. In other words, the second wiring layer 22 does not include a portion that extends along the top face of the substrate 1 as the re-wiring portion 21 does.

The barrier metal wiring 4 and 7 may be constituted using, for example, a single-layer film made of Ti, Cr, Ta or Pd, or a laminate film including Ti and Ni. Although it is not essential to provide the barrier metal wiring 4 and 7 in the present invention, it is preferable for them to be provided since, in general, adhesion between the passivation film 3 and the aluminum wiring 5 is insufficient if the aluminum wiring 5 is formed directly on the top face of the passivation film 3, and adhesion between the aluminum wiring 5 and the copper wiring 8 is insufficient if the copper wiring 8 is formed directly on the top face of the aluminum wiring 5 that has been exposed to the air. Note that in the case where the wiring 5 and 8 is formed by a PVD (Physical Vapor Deposition) method in the present invention, adhesion and cladding force can be adjusted by controlling the cladding energy. Accordingly, the need to provide the barrier metal wiring 4 and 7 is lower in this case than with a conventional WLP.

As shown in FIG. 1, the protective insulating film 11 covers the entirety of the top face of the substrate 1 other than the regions where the solder balls 9 are formed. Although there are no particular limitations on the material of the protective insulating film 11, it is preferable to use a film formed from an electrically insulating inorganic material using a PVD method or a material obtained by causing a liquid organic insulating material to harden through curing or the like.

According to this structure, the protective insulating film 11 covers the entirety of the top face of the wiring layer 21 other than the portion that is covered by the wiring layer 22. Similarly, excluding the portion that is covered by the solder balls 9 (first portion), the protective insulating film 11 covers the entirety of the top face of the wiring layer 22 (second portion).

### First Embodiment

Next is a description of a method for manufacturing a wafer level package according to a first embodiment of the present invention.

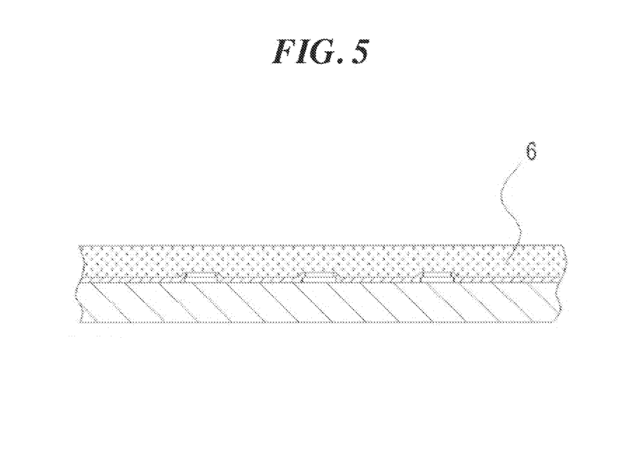

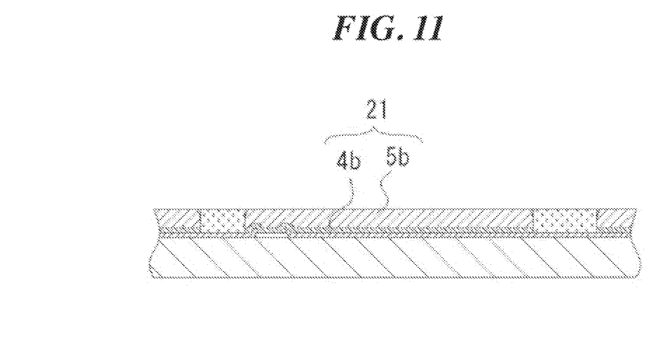

FIGS. 5 to 16 are process diagrams for illustrating the method for manufacturing a wafer level package according to the first embodiment of the present invention. FIGS. 5 to 10 correspond to cross-sectional diagrams at a place where the chip lead-out electrodes 2 shown on the left side in FIG. 2 are aligned in the Y axis direction. FIGS. 11 to 16 correspond to cross-sectional diagrams of one of the chip lead-out electrodes 2 shown on the left side in FIG. 2, the wiring layer 21, and a solder ball (external terminal electrode) 9, taken along the X-axis direction.

First, the substrate 1, on which front-end processing has been completed, is prepared, and as shown in FIG. 5, the top face of the substrate 1 is covered with the resin 6 with superior insulating characteristics (resin coating step). It is desirable that the resin coating film has a thickness of approximately 5 μm to 30 μm, but there is no particular limitation to this. The material of the resin 6, which is a feature of the present invention, will be described later.

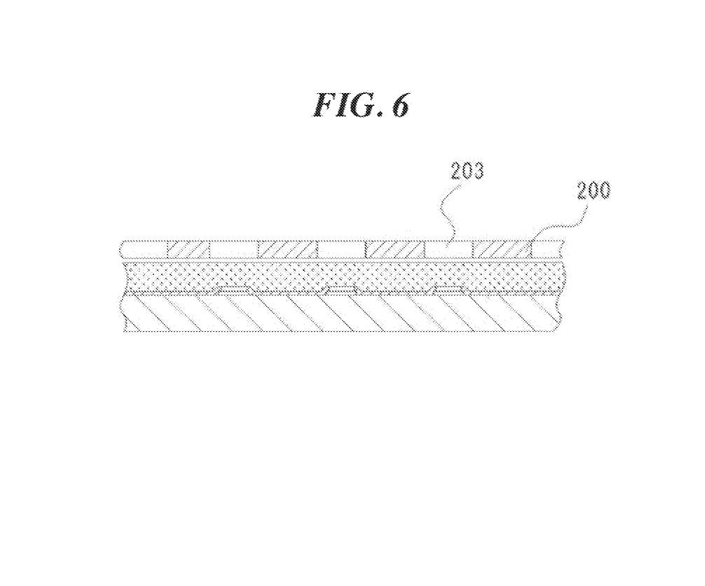

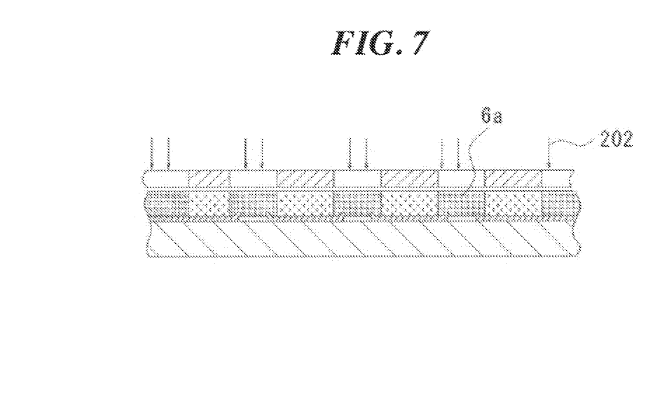

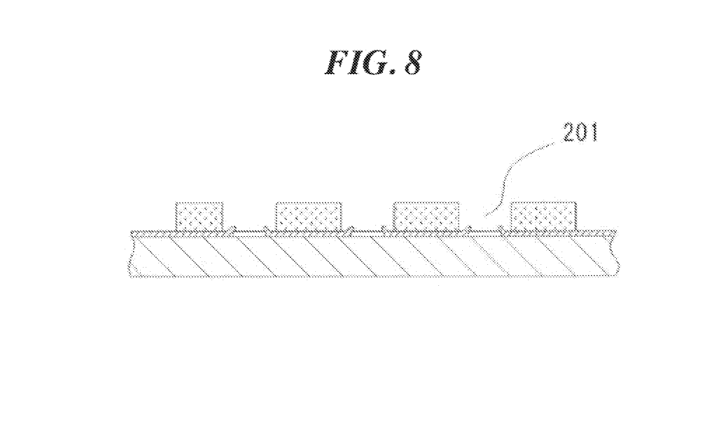

Next, removal of the resin 6 is performed so as to form grooves 201 shown in FIG. 8 in regions where the wiring layer 21 (FIG. 1) is to be formed (groove formation step). The resin removal is performed using a photolithography method, for example, thus enabling fine processing for forming grooves of a width (re-wiring width) of 10 μm or less. As shown in FIG. 6, in this step, a mask 200 including opening portions 203 at regions where grooves are to be formed in the resin 6 is placed over the resin 6, and then as shown in FIG. 7, the resin 6 is irradiated with exposure light 202 through the opening portions 203 so as to form exposed resin 6a in regions that are to serve as the grooves 201.

Next, the mask is detached (lift-off step), curing is performed, and then the exposed resin 6a is removed by cleaning (developing step) so as to form the grooves 201 (FIG. 8).

Note that although a positive method is described as being used in the photolithography step for forming the grooves 201, there is of course no problem whatsoever with using a step that employs a negative method. Furthermore, there is no problem with using an etching method or a laser processing method to form the grooves 201.

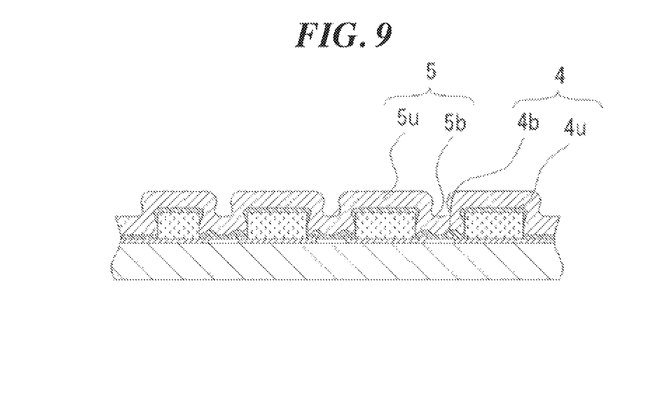

In this way, the grooves 201 are formed in regions where the wiring layer 21 is to be formed, and then as shown in FIG. 9, the barrier metal material 4 and the aluminum 5 are deposited in the stated order on the entire face of the substrate 1 through a PVD method without using a mask (film formation step). The barrier metal material 4b and the aluminum 5b that are deposited inside the grooves 201 here will form the first wiring layer 21 after a later step is performed.

Note that the aluminum 5b may instead be copper (Cu), and in the case of copper (Cu), the laminate layer can be formed using a plating method instead of a PVD method. In the case of laminating copper (Cu), it is possible to select either a PVD method or a plating method.

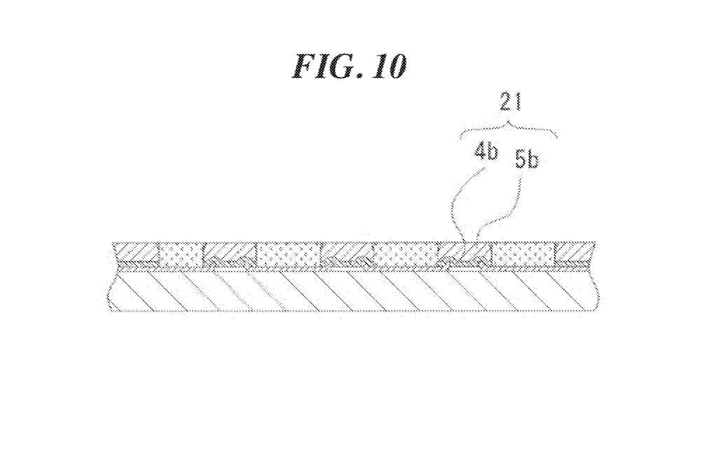

After the film that is to serve as the first wiring layer 21 has been deposited, a cutter is used to cut from the top face of the formed film parallel to the top face of the substrate 1, thereby removing portions 4u and 5u and leaving only the wiring layer 21 inside the grooves 201 formed by the resin (cutting step). This completes the formation of the wiring 21 (see FIGS. 10 and 11). Note that there is no problem whatsoever with a portion of the resin 6 being cut in the cutting step. Regarding the position (height) from the top face (or bottom face) of the substrate 1 to the cutter, it is most desirable that the cutting line (scan line) is at a position (height) at which the barrier metal material 4 is not present. This will be described in detail later.

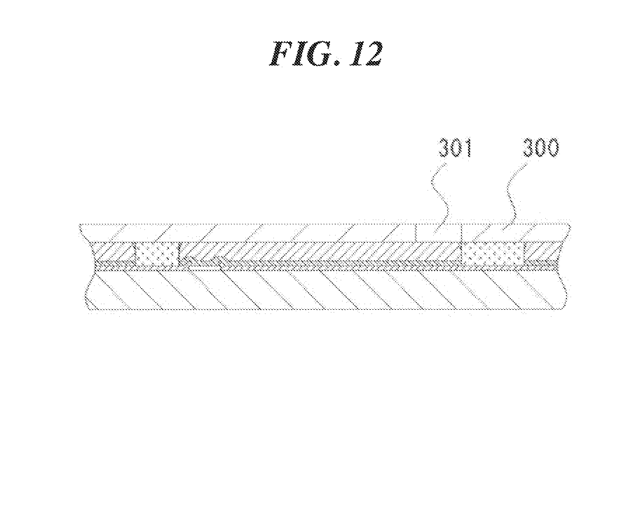

Next, the second wiring layer 22 is formed. As shown in FIG. 12, the second wiring layer 22 is formed by preparing a metal mask 300 that is provided with an opening portion 301 corresponding to the planar shape of the wiring layer 22, and the metal mask 300 is placed over the substrate 1 such that the region of the top face of the substrate 1 where the wiring layer 22 is to be formed will be exposed via the opening portion 301 (mask step).

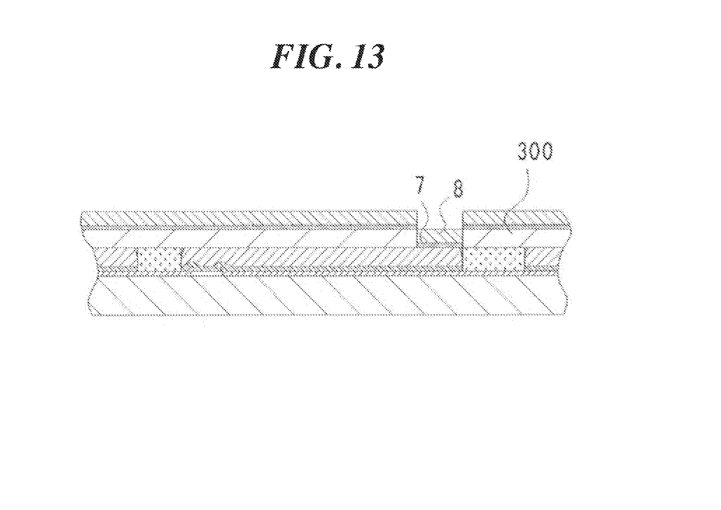

Next, the barrier metal material 7 and copper 8 are deposited in the stated order using a PVD method with the metal mask 300 placed over the substrate 1 as shown in FIG. 13 (film formation step). Accordingly, the barrier metal material 7 and copper 8 accumulate on the upper face of the metal mask 300 and the top face of the substrate 1 (more specifically, the top face of the aluminum wiring 5b) that is exposed via the opening portion 301 of the metal mask 300.

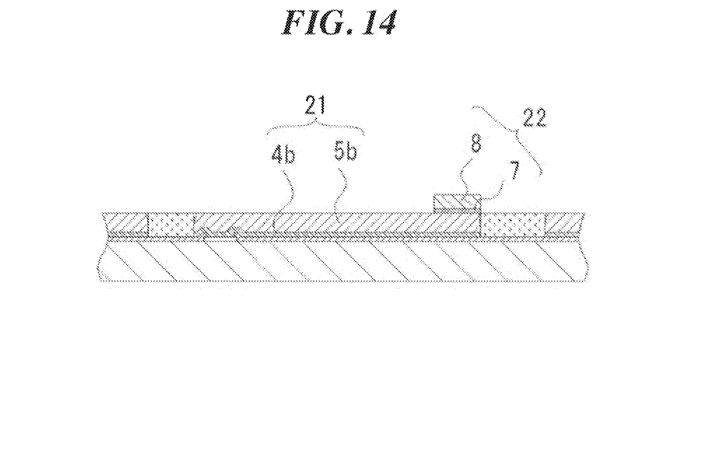

Then, as shown in FIG. 14, when the metal mask 300 is detached from the substrate 1 (lift-off step), the second wiring layer 22 made up of the barrier metal wiring 7 and the copper wiring 8 is formed without using a photolithography method.

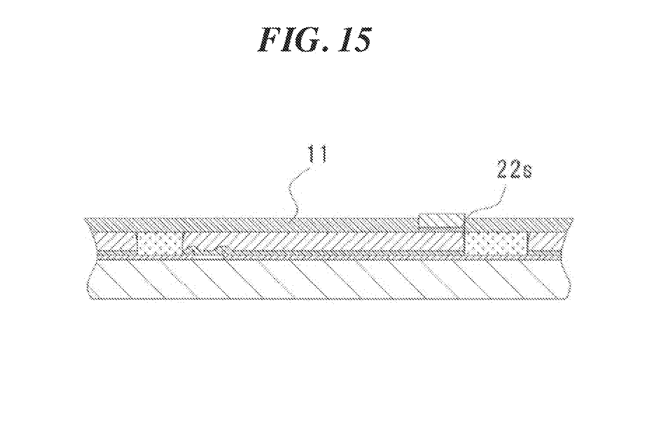

Next, as shown in FIG. 15, a PVD method is used to selectively deposit an inorganic material with electrical insulating characteristics on the top face of the substrate 1 excluding the portion where the solder ball 9 is to be formed (protective insulating film formation step). By selectively supplying the insulating material, the entire face of the wiring layer 21 and a side face 22s of the wiring layer 22 are covered by the protective insulating film 11. Since the wiring layer 22 protrudes the most outward from the substrate in the stage before the supply of the insulating material, selectively supplying the insulating material so as to avoid the wiring layer 22 enables preventing the entirety of the upper face of the wiring layer 22 from being covered by the insulating material. Note that the protective insulating film 11 may be formed by a method of selectively supplying a liquid insulating material using a screen printing method and then performing hardening through curing.

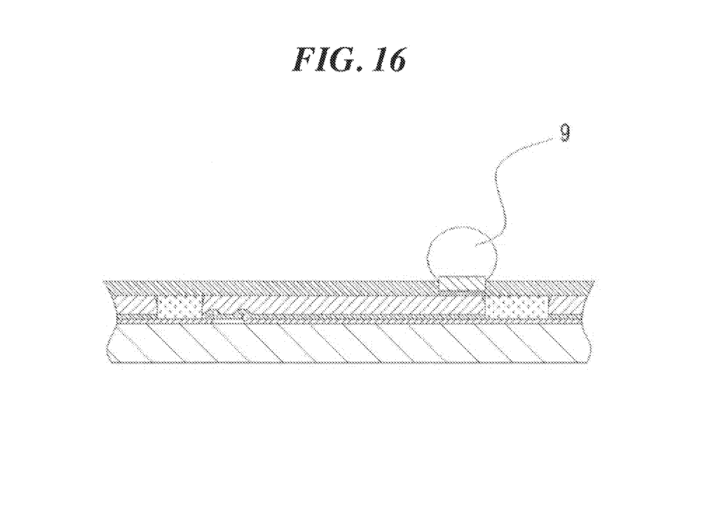

Thereafter, solder is supplied to the exposed portion of the wiring layer 22 and melted so as to form the solder ball 9 as shown in FIG. 16 (electrode formation step). This completes the series of WLP steps. Thereafter, the substrate 1 can be separated into individual semiconductor chips by being diced along scribe lines (dicing step). Note that the dicing of the substrate 1 may be performed after the formation of the protective insulating film 11 and before the formation of the solder balls 9. Furthermore, post electrodes of the wiring layer 22 can be considered to be the external terminal electrodes instead of the solder balls 9.

As described above, according to the method for manufacturing the silicon wafer 10 of the present embodiment, the wiring layers 21 and 22 are directly formed by PVD film formation being performed two times and a photolithography step being performed one time. Furthermore, unlike a WLP manufactured using a conventional photolithography method, the resin 6 that forms the surrounding walls of the grooves 201 is not removed, and is a portion constituting the WLP. The resin 6 is sometimes called a “permanent resist”. Accordingly, the number of steps is reduced to half or less than that in the case of a conventional WLP that is manufactured using a general method. Moreover, the mask 200 and the mask 300 can be inexpensively mass-produced and used repeatedly. This enables providing a high-yield, low-cost silicon wafer 10.

Wafer Level Package Manufacturing Method

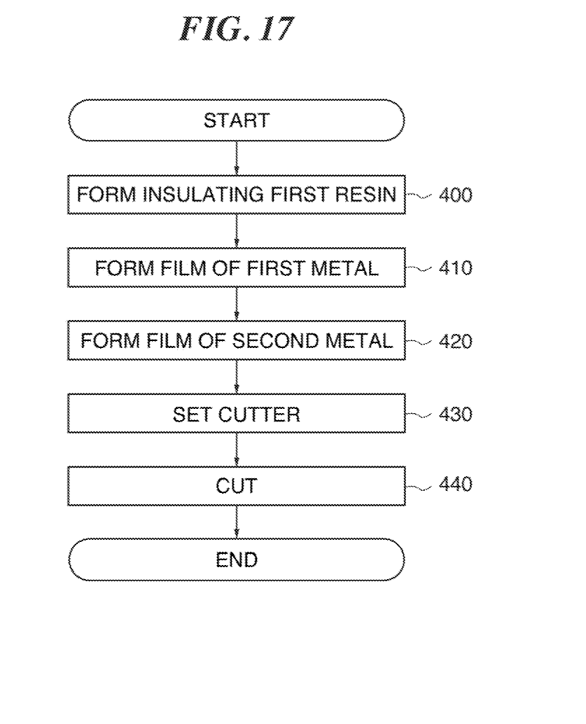

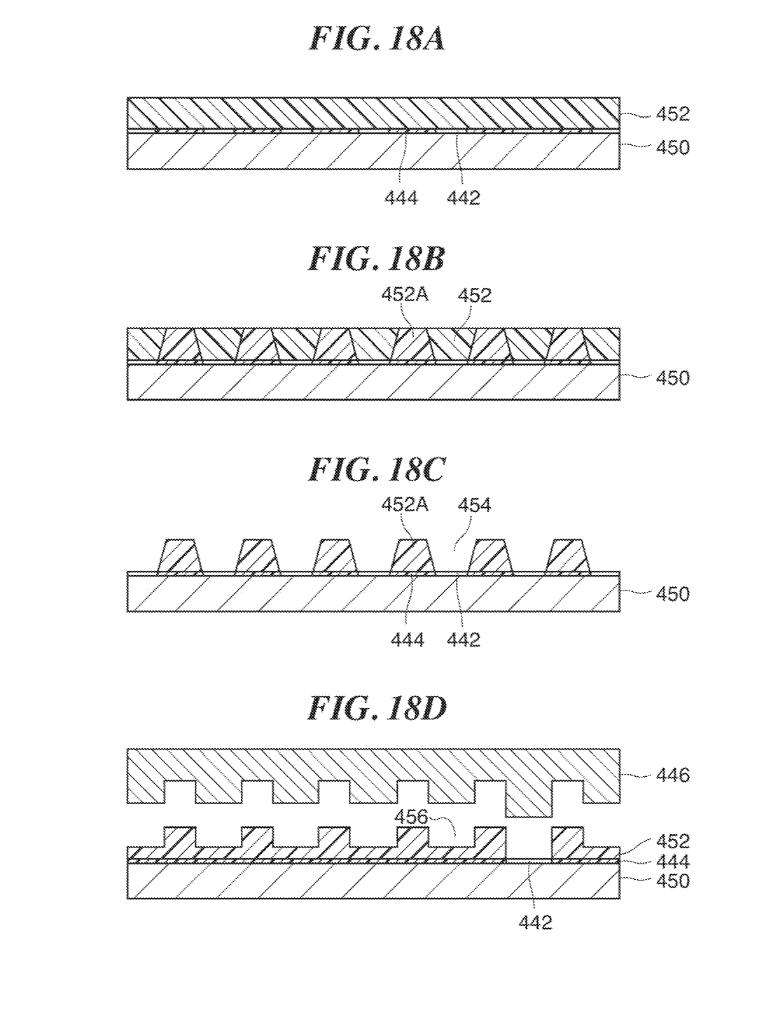

FIG. 17 is a flowchart showing a process flow that is common to second to seventh embodiments of the WLP manufacturing method of the present invention. Note that the process flow of FIG. 17 applies to the above-described first embodiment as well. FIGS. 18A to 18D are schematic diagrams illustrating an example of changes in a WLP manufactured according to the flowchart of FIG. 17.

As shown in FIG. 18, a substrate 450 is used in this method, and the substrate 450 may serve as a semiconductor substrate (e.g., a silicon wafer), for example. Internal terminal electrodes (chip lead-out electrodes) 442 and a passivation film 444 made of an insulator are arranged on the substrate 450 (where there is no particular need for distinguishing between these members, they will be collectively referred to as the substrate 450).

In the present method, first a step 400 of forming insulating first resin (FIG. 17) is performed to form insulating first resin 452 that has recessions and projections on the top face of the substrate 450. In the step 400, the first resin 452 is applied to the top face of the substrate 450 as shown in FIG. 18A for example. A main component of the first resin 452 may be phenol resin, unsaturated polyester resin, melamine resin, or urea resin.

Next, as shown in FIGS. 18B and 18C, portions of the first resin 452 (at positions of the internal terminal electrodes 442) are removed through a photolithography method so as to form grooves 454 between remaining first resin portions 452A. When the grooves 454 are formed, the first resin 452 is irradiated with ultraviolet light via a photomask (not shown) so as to form exposed portions 452 and the unexposed first resin portions 452A (FIG. 18B). The substrate 450 is then immersed in a developing liquid so as to remove the exposed portions 452, thus forming the grooves 454 between the remaining first resin portions 452A as shown in FIG. 18C. The first resin portions 452A correspond to “projections”, and the grooves 454 correspond to “recessions”. From the viewpoint of the substrate 450, the “recessions” in the first resin 452 are both grooves and holes. This can of course be understood from the shape of the resin 6 serving as the material for insulating the wiring layer 21 shown in FIGS. 2 and 4. Note that the first resin 452 is the same as the resin 6.

It should also be noted that the technique used in the step 400 is not limited to the above-described photolithography method. As shown in FIG. 18D, grooves 456 may be formed by nanoimprinting in which a nano-stamper 446 formed including a nanoscale recession-projection pattern is pressed against the first resin 452 so as to transfer the recession-projection pattern.

It is sufficient that the first resin 452 formed in the step 400 in this way has height differences (i.e., recessions and projections) due to the grooves 454 or 456. A configuration is possible in which the bottom of the grooves does not include the first resin 452 as with the grooves 454 in FIG. 18C, and a configuration is possible in which the bottom of the grooves includes the first resin 452 as with the grooves 456 in FIG. 18D.

In the present method, as shown in FIG. 17, after the step 400, a step 410 is performed to form a film of first metal 470 that is to serve as a portion of wiring, and a step 420 is performed to form a film of second metal 480 that is to serve as a portion of wiring. In both the step 410 and the step 420, films of the first metal 470 and the second metal 480 are formed through a PVD (Physical Vapor Deposition) method. Examples of PVD methods include vapor deposition (resistance heating vapor deposition, electron beam vapor deposition, molecular beam epitaxy, and the like), ion plating, ion beam deposition, and sputtering.

This method further includes a step 430 of setting a cutter 490 at a predetermined position, and a step 440 of cutting and planarizing the metal (wiring) and the first resin using the cutter 490. These steps will be described below in various embodiments of the present invention.

### Second Embodiment

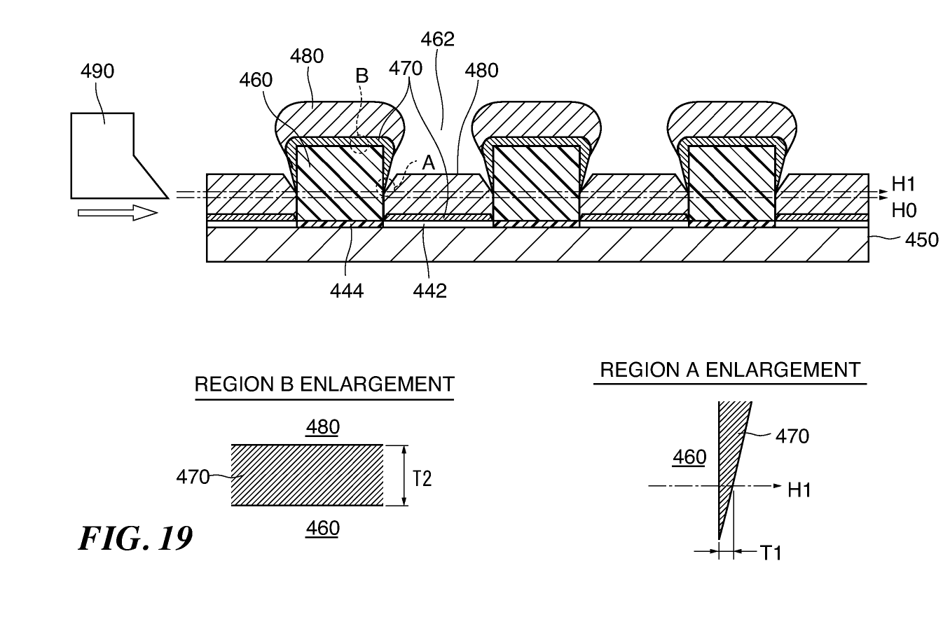

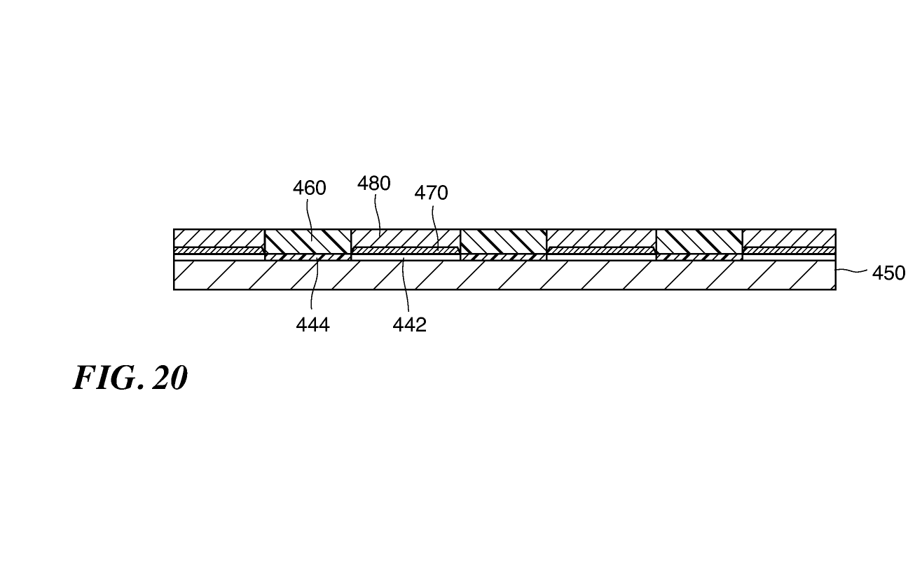

FIG. 19 is a diagram illustrating a second embodiment of the WLP manufacturing method of the present invention. FIG. 20 is a diagram illustrating an intermediate wafer level package obtained as a result of completion of the WLP manufacturing method in FIG. 19.

In the present embodiment, in the step 400 of FIG. 17, first resin 460 that is adjacent to grooves 462 is formed so as to have a rectangular cross section. The first resin 460 and the grooves 462 were formed through the step 410 of forming a film of the first metal 470 of a relatively high hardness and the step 420 of further forming a film of the second metal 480 of a relatively low hardness. As a result, the film formation state shown in FIG. 19 was obtained.

The first metal 470 may be Ti, Cr, Ta, or Pd, and the second metal 480 may be Cu or Al. As can be understood from these materials, there is a difference in hardness between the first metal 470 used as barrier metal and the second metal 480 used as wiring metal.

Next, as shown in FIG. 17, the step 430 is performed. In the step 430, the cutter 490 is set at a height H0, which is a height corresponding to a place where there is no film of the first metal 470 that was formed on the side faces of the grooves 462 (side walls of the first resin 460) in FIG. 19, that is to say, where the thickness is zero, and the first resin 460 and the second metal 480 are cut. As a result, the intermediate WLP shown in FIG. 20 was obtained. Regarding the cutter 490, for example, such as a bit(beitel) or a cutting tool made of diamond, the cutter 490 comprises the part which is an acute angle in relation to a cutting part of the first resin 460 and the second metal 480 corresponding to the height H0).

According to the present embodiment, as a result of the step 410, a film of the first metal 470 of a relatively high hardness is formed from the upper face of the first resin 460 to the upper portion of the side faces of the grooves 462 as shown in FIG. 19. However, the thickness of the film of the first metal 470 formed on the side faces of the first resin 460 gradually decreases when moving farther downward, and eventually reaches zero. Next, when the step 420 is performed, a film of the second metal 480 is formed on the film of first metal 470 that was formed on the bottom of the grooves 462, the upper face of the first resin 460, and the upper portion of the side faces of the grooves 462, as shown in FIG. 19. Note that similarly to the wiring 5 in FIG. 9, a film of the second metal 480 may be formed so as to fill the grooves 462 in the step 420. It should also be noted that the thickness of the film of first metal 470 formed on the upper face of the first resin 460 and the thickness of the film of first metal 470 formed on the bottom portion of the grooves 462 are substantially the same thickness.

Cutting By Cutter Where Film of First Metal Was Not Formed

A feature of the present embodiment is that after the above-described film formation is performed, in the step 430, the cutter 490 is positioned along a cutting line at the height H0 corresponding to a place where no film of the first metal 470 was formed, that is to say, where the thickness is zero, and in the step 440 shown in FIG. 17, cutting is performed by scanning the cutter 490 along the top face of the substrate 450. Accordingly, only two types of material are cut by the cutter 490, namely the first resin 460 that is the softest, and the second metal 480 whose hardness is relatively lower than that of the first metal 470. Note that the thickness of the film of second metal 480 is arbitrary and not directly related to the height H at which the cutter 490 is set. For example, if the thickness of the film of second metal 480 is low, there are cases where only the first resin 460 is cut by the cutter 490 at the cutting line of height H0. As another example, if the thickness of the film of second metal 480 is low, there are cases where the cutting line of height H1 is the top face of the second metal 480 formed in the grooves 462. Note that “the softest” refers to the softest material among the materials that are to be cut. It should also be noted that the case of fixing the cutter 490 and scanning the substrate 450, and the case of scanning them both independently are also included in the technical scope of the present invention.

In the case where cutting is performed at a height higher than the height H0, three types of material, further including the first metal 470, are cut since a film of the first metal 470 of a relatively high hardness is also formed on the side faces of the grooves 462. A comparison with this case shows that in the present embodiment, there is less wearing of the cutter 490, and the lifetime of the cutter 490 can be maximized.

Cutting By Cutter Where Thickness of Film of First Metal is Low

Note that in the step 430 and the step 440, if the thickness of the film of the first metal 470 of the highest hardness that was formed on the side faces of the grooves 462 is low, cutting may be performed at that height. For example, as shown in the enlarged view of region A in FIG. 19, the film thickness T1 of the first metal 470 at the height H1 is lower than the thickness T2 of the same film of the first metal 470 formed on the upper face of the first resin 460 (see the enlarged view of region B in FIG. 19). Cutting may be performed at the cutting line of height H1.

According to the above-described configuration, the cutter 490 cuts three types of materials, namely the first metal 470, the second metal 480, and the first resin 460, but the film thickness T1 of the first metal 470 is low enough to satisfy the above-described condition. Compared to the case of cutting at a position even higher than the height H1, in this configuration there is less wearing of the cutter 490, and the lifetime of the cutter 490 can be extended.

Resin of Rectangular Cross Section

Furthermore, in the present embodiment, the side faces of the first resin 460 are perpendicular faces since the first resin 460 has a rectangular cross section. Accordingly, the film thickness of the first metal 470 gradually decreases when moving downward along the side faces of the first resin 460 and eventually reaches zero, thus enabling realizing a structure to which the step 440 of the present embodiment can be applied.

### COMPARATIVE EXAMPLE

Patent Document 1 will be used as an example for comparison with embodiments of the present invention. Patent Document 1 (Japanese Patent Laid-open Publication No. H7-326614) discloses technology according to which a cutter 6 is brought into contact at a position that is on an edge face of an SiO2 interlayer insulating film 22 and is somewhat lower than the interface with a barrier metal 24, and cutting is performed in the X direction, as disclosed in FIG. 10 and the corresponding paragraphs of the same document. However, there is no disclosure whatsoever of a problem related to the hardness of the barrier metal 24 or degradation (wearing) of the cutter, and no consideration is given to the height of the cutter from the viewpoint of preventing degradation of the cutter, nor is any disclosure or suggestion thereof made. Also, no consideration is given to the relationship between the material of the later-described interlayer insulating film 22 and the cutter, nor is any disclosure or suggestion thereof made. Patent Document 5 (EP2075825) is similar to Patent Document 1, too.

On the other hand, the present invention has remarkable effects of enabling suppressing the wearing of the cutter by strictly prescribing the relationship between the set height of the cutter and the first metal 470, and of improving cutting performance as well. Furthermore, the present invention has remarkable effects of enabling suppressing the wearing of the cutter by strictly prescribing the later-described relationship between the cutter and the material of the first resin 460 serving as an electrical insulator, and of improving cutting performance as well.

Reason Why Wearing of Cutter is Suppressed By Present Invention

As previously described, as the amount of cutting of the first metal 470 that has a relatively high hardness increases, or in other words, as the percentage of the linear length of the cutting line that is occupied by the linear length of the first metal 470 increases, the wearing of the cutter 490 increases, and therefore a feature of embodiments of the present invention is that the amount of the first metal 470 that is cut is suppressed to a minimum by performing cutting at a place where the thickness of the first metal 470 is low or a place where it is zero. The following considers physical constants and the wearing of the cutter 490.

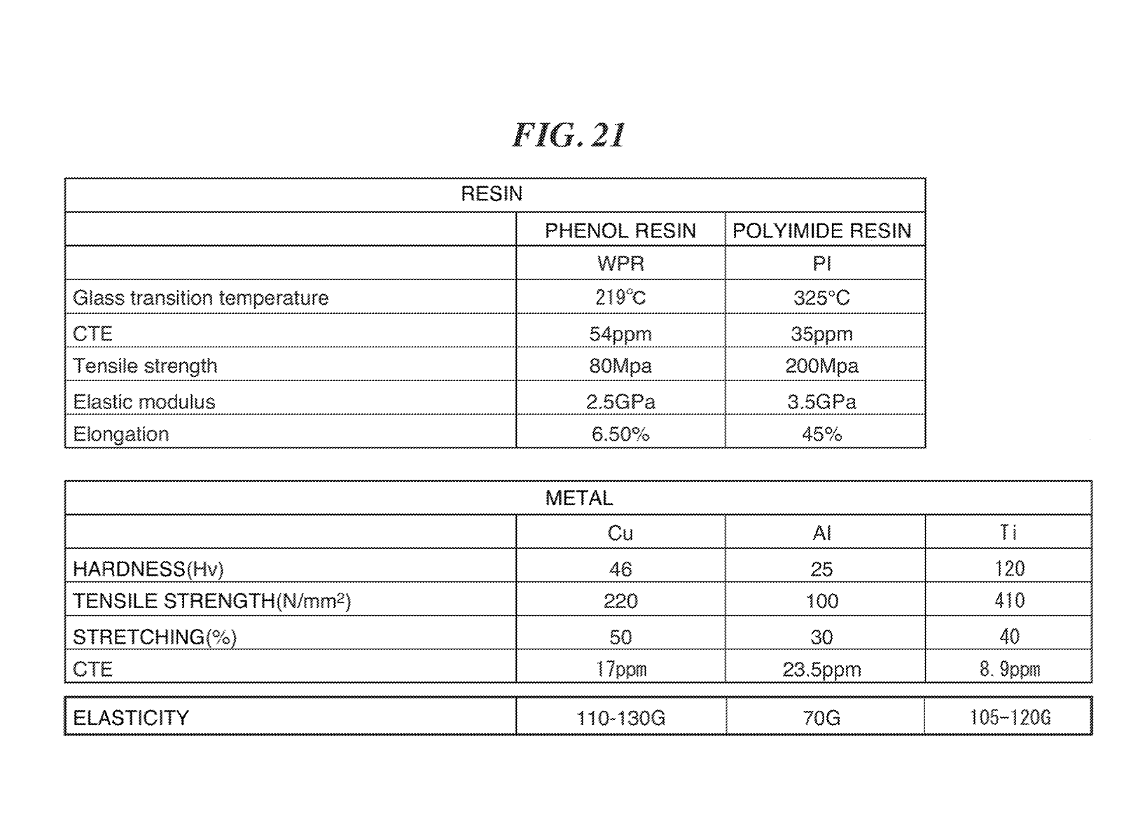

FIG. 21 is a table showing physical properties of the various types of resins and metals used in embodiments of the present invention. FIG. 21 shows phenol resin as a representative material that can be used as the first resin 460 (the same follows for the “first resin” denoted by other reference numbers as well). Also, Ti is shown as a representative metal that can be used as the first metal 470, and Cu and Al are shown as representative metals that can be used as the second metal 480. Note that polyimide resin is used as an example for comparison with phenol resin.

When performing cutting with the cutter 490, the material that is cut has resistance against the cutter 490, and therefore causes for wearing of the cutter 490 include firstly the hardness of the material that is cut, and secondly the stickiness of the material (i.e., the degree of elastic elongation). This is because when the cutter 490 cuts a sticky material, the cutter 490 drags uncut material. Since the hardness and stickiness of Ti are both high, it is a material that causes wearing of the cutter 490.

However, in embodiments of the present invention, cutting is performed at a height corresponding to a place where the film of the first metal 470 of a high hardness (typified by Ti) is not formed or a place where the thickness of the film of the first metal 470 is low. This suppresses the amount of the first metal 470 that is cut. Accordingly, it is possible to suppress the wearing of the cutter 490 and significantly extend the lifetime thereof.

Also, phenol resin in general has a large number of network-forming groups such as functional alkyl groups and hydroxyl groups that are necessary for a polymer structure, which have a denser three-dimensional structure than network-forming groups such as imide groups in a polyimide. Accordingly, phenol resin has a comparatively high elasticity, high hardness, and small range of plastic deformation (craze deformation). In particular, phenol resin has mainly an annular structure, and therefore does not cause a problem such as degradation of processing performance due to the attachment of cutting target material to the cutter, and is easily cut. In this way, reducing the characteristics-related differences with the metal in terms of cutting enables eliminating problems in terms of processing.

Reason Why Cutting Performance is Improved By Present Invention: First Resin Material

As previously described, besides phenol resin, a main component of the first resin 460 may be unsaturated polyester resin, melamine resin, or urea resin. This is because it is desirable to use a thermoset resin that does not undergo plastic deformation due to local heat generation during cutting by the cutter. This is also because it is thought that it is favorable for the first resin 460 to be a resin that has appropriate elasticity, has low distortion with respect to critical stress, and has a relatively low strength, in order to improve the cutting by the cutter.

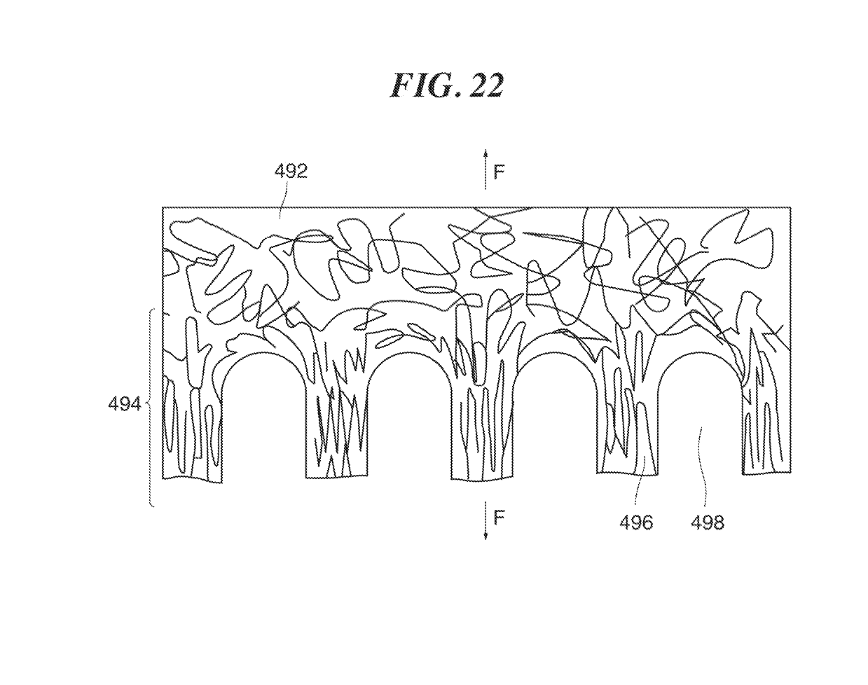

FIG. 22 is a schematic diagram illustrating an example of crazing that occurs in resin (polyimide resin or the like) that is not suitable as the first resin 460 in FIG. 19. Here, “crazing” refers to the state in which two-dimensional chains of two-dimensionally entangled atomic chains align and cutting becomes difficult. As shown in FIG. 22, when force F is applied when a plastic bag is opened, a phenomenon occurs in which the bag becomes divided into an organic bulk portion 492 and a craze portion 494 that stretches and turns white, and there is a very large amount of resistance. The craze portion 494 that appears to have turned white includes fibrils 496 that are microfibers and voids 498 that are gap portions.

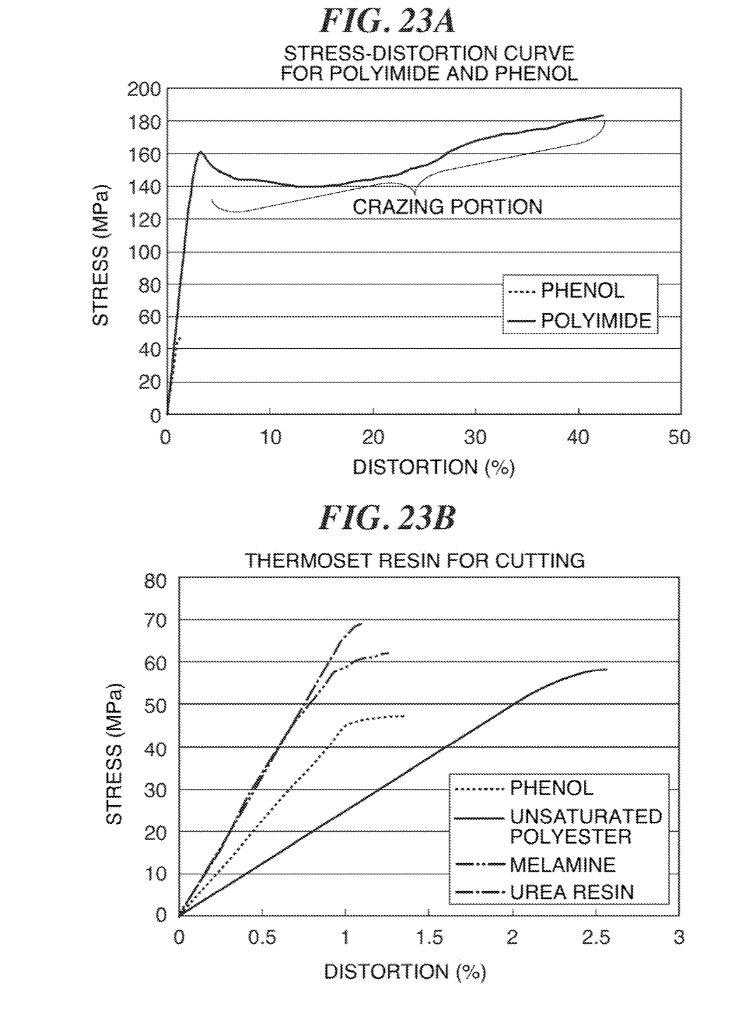

FIGS. 23A and 23B are graphs showing stress-distortion curves for various types of resin. It is preferable that the first resin 460 is a resin with a distortion percentage due to stress of several percent or lower, and such a resin is a material that does not tend to undergo crazing and has a low amount of sticking to the cutter. As shown in FIG. 23B, the above-described phenol resin, unsaturated polyester resin, melamine resin, and urea resin all satisfy these conditions. This is because they contain it-shaped cyclic groups that are hard and undergo little stretching.

On the other hand, as shown in FIG. 23A, polyimide resin is a high-strength resin with a distortion percentage due to stress on the order of several tens, and the crazing shown in FIG. 22 readily occurs. Accordingly, polyimide resin is not suitable as the material of the first resin 460 since there is the risk of lowering the cutting performance of the cutter 490.

The following describes a definition of the statement that phenol resin, unsaturated polyester resin, melamine resin, or urea resin is “a main component”.

Types of phenol resin include novolac resin, which is polymerized by causing condensation polymerization of a mixture of phenol and formaldehyde using an acid catalyst, and resol resin, which is polymerized by causing condensation polymerization using an alkali catalyst. The former has thermoplasticity as it is, and is a liquid in the low-molecular state. Condensation polymerization is caused by mixing in a curing agent such as hexamethylenetetramine at 1 to 20 wt %, thus obtaining a thermoset resin. The latter itself has an auto-reactive active group, and therefore thermosets by being heated.

Novolac resin, for which the thermosetting polymerization reaction is easily controlled, is mainly used in electronic parts applications. The member referred to as the permanent resist in this specification is of the novolac type, and in the case of being processed as a photoresist, 100% of the permanent resist is made up of novolac phenol resin. In the case of use as a material other than a photoresist, such as a coating material, there are cases where various types of high-strength macromonomers, bulking agents such as cellulose, pigments (particularly black pigment and the like), fillers (silica glass microparticles), and the like are added at approximately 0.1 to 50 wt % with respect to the total additive weight.

As can be understood from the stress-distortion curve in FIG. 23A, phenol resin stretches little and does not have a very high strength, and is brittle as an electronic material. In response to a demand for somewhat of an increase in strength or the like, it is possible to modify the phenol resin with epoxy (the epoxy characteristics become stronger according to the modified portion, that is to say, the mixing percentage), or modify the phenol resin with polyvinyl acetal in view of degradation of heat resistance. Also, modifications for various improvements in characteristics are performed, such as using nitrile rubber-modified phenol resin for improving thermal cycle reliability, and using rosin-modified phenol resin for raising printability. The mixture rate of such modified resin is at the level of 1% to 50 wt %. Accordingly, in this specification “includes phenol resin as a main component” is defined as meaning that phenol resin is included at 50 wt % or more.

Melamine resin is synthesized by causing a condensation polymerization reaction of methylol melamine that is obtained by causing a condensation reaction of melamine and formaldehyde, and since nitrogen-containing cyclic groups are created, melamine resin has a higher impact strength than urea resin. In general, reinforced plastic is created by impregnating fibers or the like with methylol melamine, and in the case of an electronic part, a cellulose additive is added at 5 to 40 wt %. Of course use as 100% resin is also possible. Modification to an epoxy or urea resin can be freely performed by adding appropriate amounts of an epoxy monomer or urea during synthesis. Also, a resin with intermediate characteristics can be obtained by mixing. In this specification, “includes melamine resin as a main component” is defined as meaning that melamine resin is included at 50 wt % or more.

Unsaturated polyester resin is a thermosetting resin created by causing condensation polymerization of an unsaturated polyester, such as maleic anhydride or an isophthalic acid-based polyester, and a polyol such as ethylene glycol, and a feature of unsaturated polyester resin is high mechanical strength since the maleic anhydride and styrene are cyclic groups. Accordingly, 100% resin can also be used. It is particularly superior in an application as a reinforced plastic for impregnation in fibers. Countless types can be created with various types of ester compounds, and as modified resins using heterogeneous resins, conceivable modifications include the mixing of pentadiene or the like during synthesis in order to maintain the smoothness of the top face, and the mixing of compatible acrylic urethane in order to achieve transparency and prevent yellowing due to light. In general, phenol, epoxy, and urethane are reactive groups created by mixing during synthesis, and although the combining can be performed freely, in this specification, “includes unsaturated polyester resin as a main component” is defined as meaning that unsaturated polyester resin is included at 50 wt % or more.

Urea resin is synthesized by causing a condensation reaction of urea and formaldehyde, and rupture toughness degrades due to the linear chain network lacking a cyclic compound. For this reason, there are few cases of using 100% resin, and it is conceivable to, for example, perform modification by, during synthesis, adding 0.5 to 30 wt % of a glycin compound that has a bisphenol A framework, which is a cyclic compound for increasing rupture toughness. Also, cellulose is often used as a bulking agent, and mechanical properties can be adjusted by adding 5 to 40 wt % of cellulose. Compatibility with melamine resin and phenol resin is good, and adding melamine and phenol during the reaction produces intermediate properties between them. Accordingly, in this specification “includes urea resin as a main component” is defined as meaning that urea resin is included at 50 wt % or more.

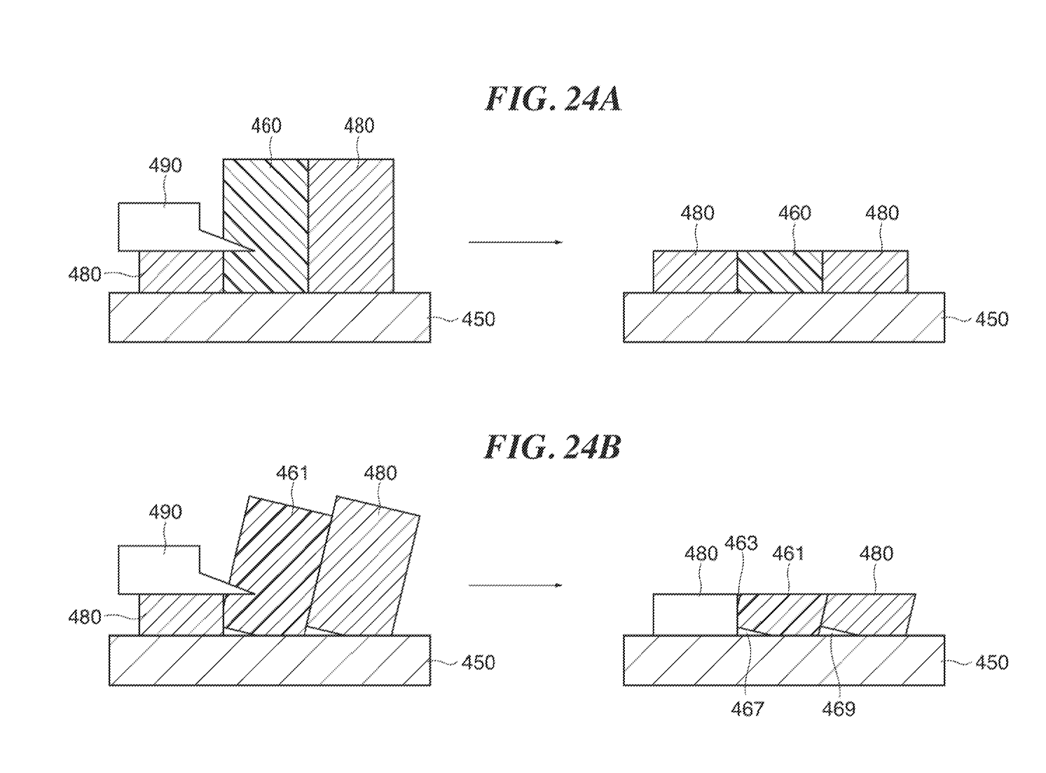

FIGS. 24A and 24B are schematic diagrams showing resin and metal after cutting at the height H0 in FIG. 19, as viewed from the cross-sectional face. FIG. 24A shows the case of using the materials in FIG. 19 as they are, and the first resin 460 (phenol resin or the like) and the second metal 480 (Cu or Al) are cut alternately. On the other hand, FIG. 24B shows the case of changing the first resin 460 in FIG. 19 to a polyimide resin 461. In the case of using the materials in FIG. 19 as they are, cutting is performed without any problems, as shown in FIG. 24A. Since the first resin 460 is hard and stretches little, a gap does not tend to be formed between it and the adjacent second metal 480 that is cut at the same time during cutting. Also, the first resin 460 does not tend to detach from the substrate 450. This has a remarkable effect of preventing distortion of the wiring pattern of the metal that forms wiring.

However, as shown in FIG. 24B, when the polyimide resin 461 is used instead of the first resin 460, due to the high strength thereof, the polyimide resin 461 becomes distorted due to being pushed by the cutter, a gap 463 is formed between it and the previously cut second metal 480 (on the left side), and a detached portion 467 is formed where detachment from the substrate 450 occurs. Also, when the polyimide resin 461 becomes distorted, the second metal 480 that is to be subsequently cut (on the right side) also becomes distorted, and a detached portion 469 is also formed where the second metal 480 detaches from the substrate 450.

If the above-described gaps and detached portions are formed, there is the risk of distortion of the wiring and resin patterns. Specifically, there is a tendency for metal fall-off and resin fall-off to occur, for internal voids to be formed, and the like, and there is the possibility of wiring disconnection and wiring short circuiting. Particularly in the case of wiring with a high wiring density, the area of bonding between the resin and metal, between the metal and the substrate, and between the resin and the substrate is small to begin with, and therefore there is a tendency for detachment from the metal (e.g., the gap 463) and detachment from the substrate (e.g., detached portions 467 and 469) as described above to occur. Accordingly, it is critical to use the first resin 460 that can be easily cut as shown in FIG. 24A.

Reason Why Cutting Performance is Improved by Present Invention: Passivation Film

As shown in FIG. 19, the substrate 450 comprises the passivation film 444 on at least a portion of the top face thereof, and the passivation film 444 is in contact with the first resin 460. Due to the passivation film 444 and the first resin 460 being in contact with each other, the adhesion (adhesive force) of the first resin 460 is improved, and cutting performance is further improved.

A main component of the passivation film 444 of the present embodiment is polyimide resin. Phenol resin, unsaturated polyester resin, melamine resin, and urea resin, one of which is used as the first resin 460 in contact with the passivation film 444, are all photosensitive resin that adheres to polyimide resin, and have a high adhesive force and are easily cut. This is because the material of the first resin 460 contains a relatively large amount of carboxyl groups, hydroxyl groups, or imide groups, which are reactive with carboxyl groups and imide groups, which are the reactive groups of the polyimide resin, which is the material of the passivation film 444, and are interspersed within the main chain and the subchain.

### Third Embodiment

Positive Tapered Shape of First Resin Cross Section

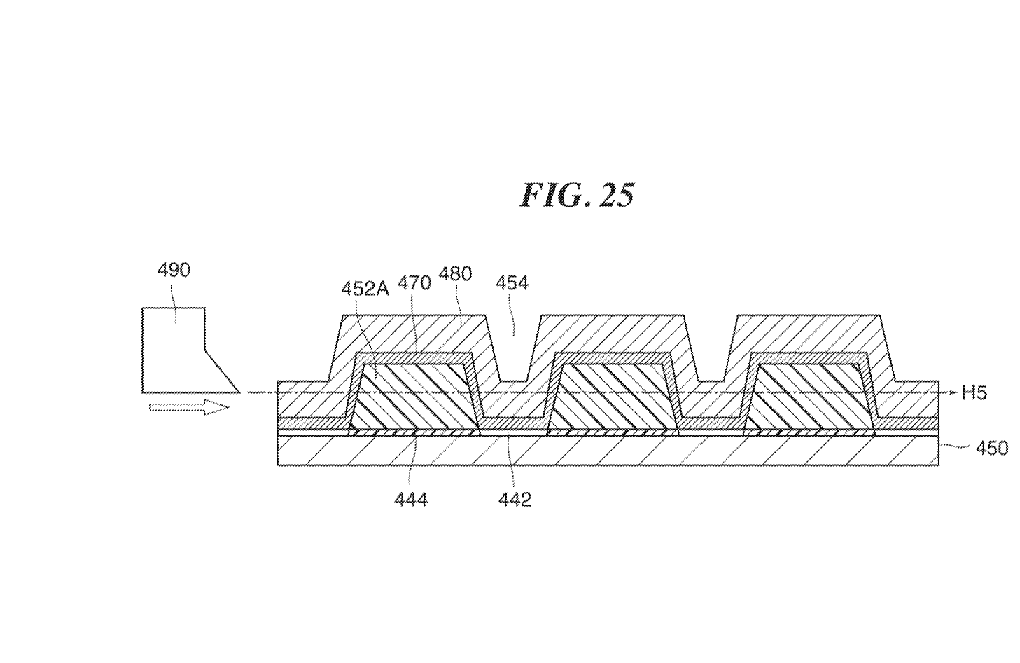

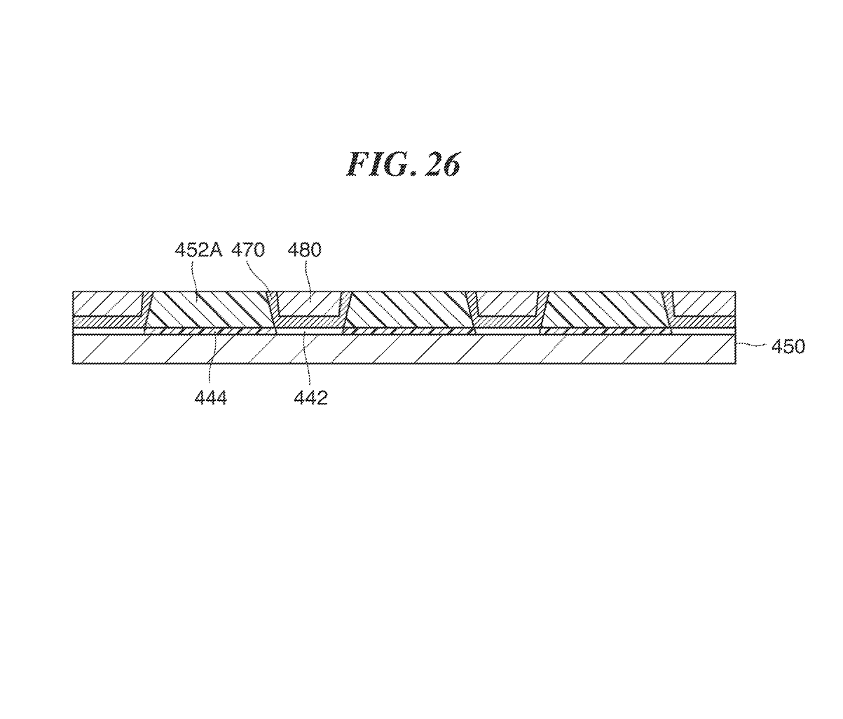

FIG. 25 is a diagram showing a third embodiment of the WLP manufacturing method of the present invention, in which the steps 410, 420, 430 and 440 are performed on the first resin 452A shown in FIG. 18C. FIG. 26 is a diagram illustrating an intermediate wafer level package obtained as a result of completion of the WLP manufacturing method in FIG. 25.

In the present embodiment, in the step 400 of FIG. 17, the cross section of the first resin portions 452A that are adjacent to the grooves 454 is a positive tapered shape, that is to say, a trapezoid whose upper base is shorter than the lower base.

In order to form the first resin portions 452A of a positive tapered cross section as shown in FIG. 25, it is sufficient to perform the step 400 using, for example, a positive resist as the first resin 452 in FIG. 18A. Specifically, a positive resist is a resist in which the exposed portions disappear in developing. This is because with a positive resist, solubility with a developing liquid increases the higher the layer in the resist film of the exposed portion, and the obtained pattern tends to be a positive tapered shape.

The cross section of the first resin portions 452A is a trapezoid with a short upper base and a long lower base. Accordingly, the side faces of the first resin portions 452A are inclined faces that spread out toward the bottom. In this case, the thickness of the film of the first metal 470 formed on the side faces of the grooves 454 is greater than that in the case of the first resin 460 (see FIG. 19) that has a rectangular cross section.

However, even if the first resin portions 452A have a positive tapered cross section, the thickness of the film of the first metal 470 that is formed gradually decreases when moving downward along the side faces of the grooves 454, and eventually becomes less than the thickness of the film of the first metal 470 formed on the upper face of the first resin portions 452A. Accordingly, if cutting is performed at the height H5 at which the relevant conditions are satisfied, it is possible to manufacture the intermediate body shown in FIG. 26 while suppressing wearing of the cutter 490.

### Fourth Embodiment

Inverse Tapered Shape of First Resin Cross Section

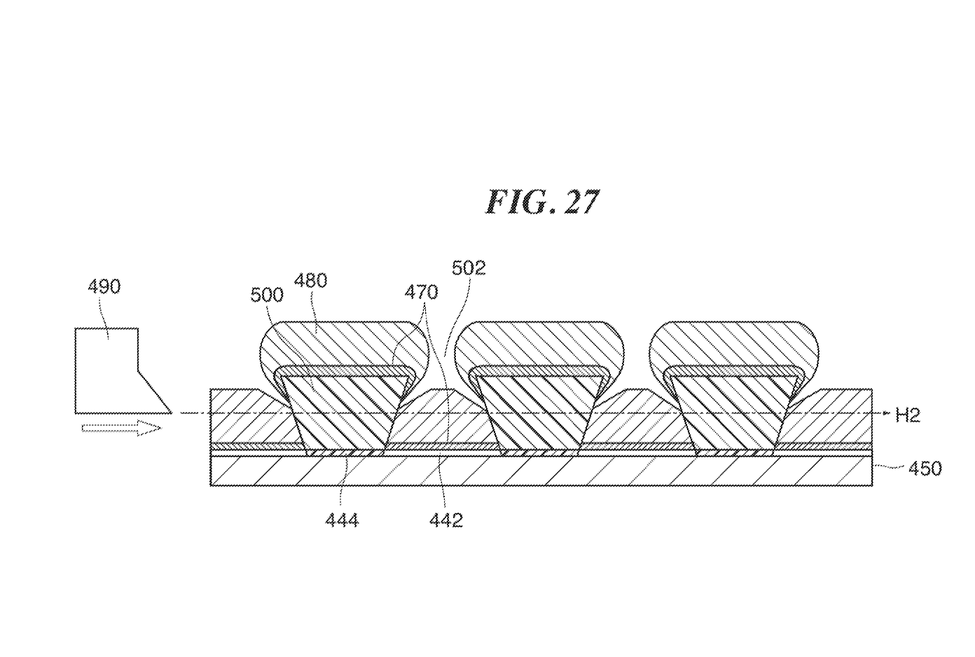

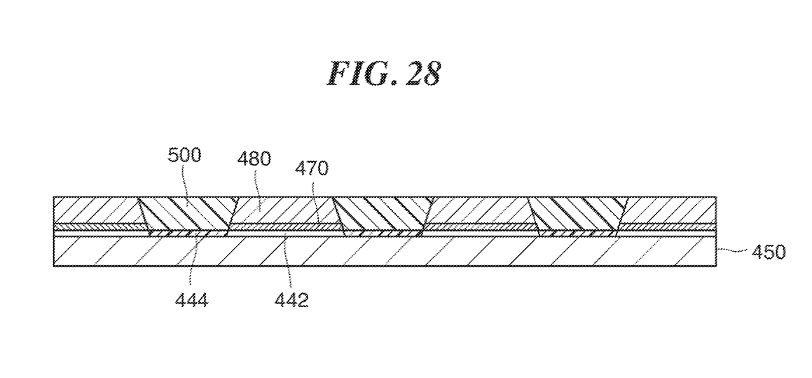

FIG. 27 is a diagram showing a fourth embodiment of the WLP manufacturing method of the present invention. FIG. 28 is a diagram illustrating an intermediate wafer level package obtained as a result of completion of the WLP manufacturing method in FIG. 27.

In the present embodiment, in the step 400 of FIG. 17, the cross section of first resin portions 500 that are adjacent to grooves 502 is an inverse tapered shape, that is to say, a trapezoid whose lower base is shorter than the upper base.

In order to form the first resin portions 500 of an inverse tapered cross section as shown in FIG. 27, it is sufficient to perform the step 400 using, for example, a negative resist. A negative resist is a resist in which the exposed portions remain in developing (unexposed portions disappear). With a negative resist, solubility with a developing liquid decreases the higher the layer in the resist film of the exposed portion, and the obtained pattern tends to be an inverse tapered shape.

Since the first resin portions 500 have this tapered cross section, the side faces of the first resin portions 500 are inclined faces that become narrower toward the bottom. The angle of inclination of the side faces of the first resin portions 500 can be controlled between approximately 45 to 80 degrees, for example, by adjusting the wavelength and intensity of the light source in exposing and developing.

Accordingly, the film thickness of the first metal 470 is even lower than that in the second embodiment that uses the first resin 460 of a rectangular cross section (FIG. 19). Specifically, the thickness of the first metal 470 drastically decreases in the upper portion of the side faces of the grooves 502. This is because it is difficult for the first metal 470 to accumulate on the steep cliff-shaped inclined faces. This enables widening the range in which the step 440 can be performed, in which the cutter 490 is set to a height at which the thickness of the first metal 470 is zero. In the present embodiment, the step 440 is performed at the cutting line at the height H2. This relaxes the manufacturing margin.

In this way, a feature of the present embodiment is that reducing the film thickness of the first metal 470 on the side face of the grooves 502 widens the range in which the thickness of the first metal 470 is low and the step 440 can be applied.

When the cross section of the first resin portions 500 is the inverse tapered shape as described above, the step 410 may be performed using a sputtering method. This is because by making the cross section of the first resin portions 500 inverse tapered, the film thickness of the first metal on the side faces of the grooves 502 decreases, and there is no need to keep the film formation thickness low through ion plating.

When the cross section of the first resin portions is the inverse tapered shape as described above, the film of second metal may be formed using an ion plating method or may be performed using a sputtering method or a plating method. This is because the film thickness of the second metal of a relatively low hardness has little influence on the wearing of the cutter and the like.

### Fifth Embodiment

Use of Metal Mask in Step of Forming a Film of First Metal

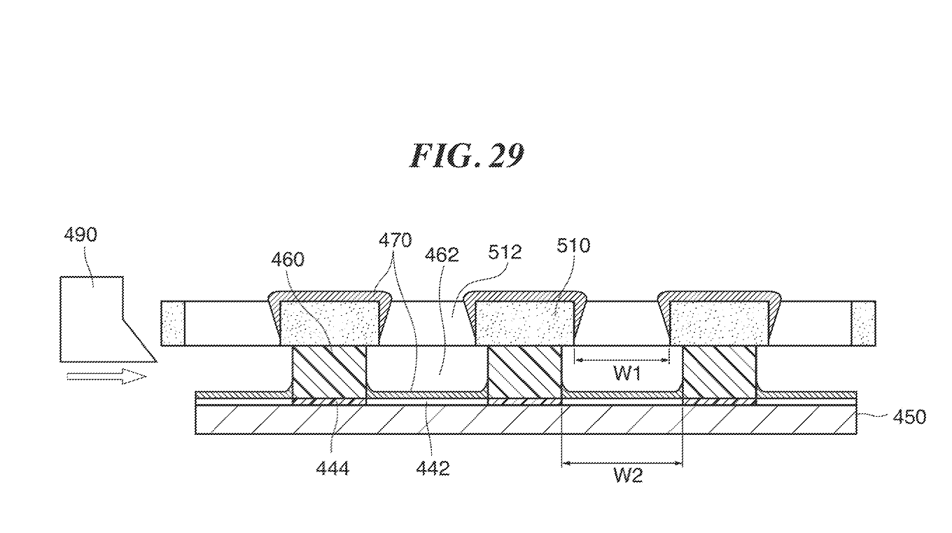

FIG. 29 is a diagram showing a fifth embodiment of the WLP manufacturing method of the present invention. In the present embodiment, in the step 400 of FIG. 17, similarly to the second embodiment, the grooves 462 are formed such that the first resin portions 460 of a rectangular cross section remain. Thereafter, the step 410 is performed using a metal mask 510 including opening portions 512 at positions corresponding to the grooves 462. As a result, as shown in FIG. 29, films of the first metal 470 are formed in the grooves 462 and on portions of the metal mask 510 positioned over the first resin portions 460. The amount of the film of the first metal 470 that is formed on the side faces of the grooves 462 is low since the metal mask 510 is used. However, it is not true that no films at all are formed on the side faces, and films of the first metal 470 are formed on the side faces as well, in the vicinity of the bottom face of the grooves 462.

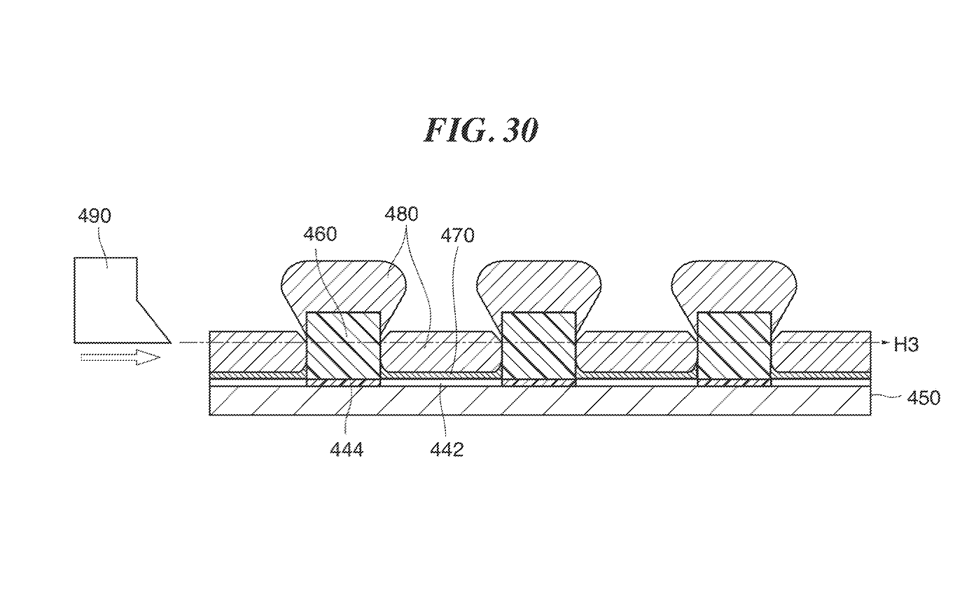

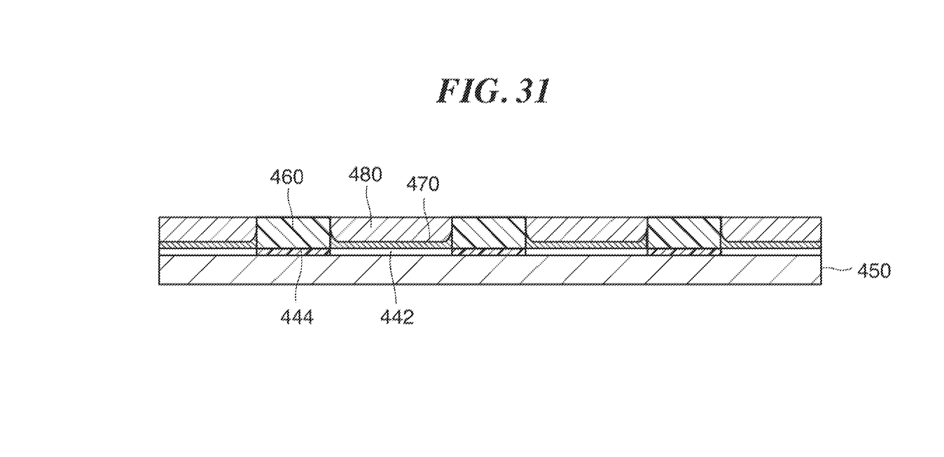

FIG. 30 is a diagram showing the result of film formation in which the step 420 was performed after the metal mask 510 was lifted off from the film formation state in FIG. 29. The film of the second metal 480 is formed on the film of the first metal 470 that was formed in the grooves 462, and only films of the second metal 480 are formed directly on the upper face of the first resin portions 460. Accordingly, in the step 440, cutting can be performed along the cutting line at the height H3 where the first metal 470 is not present, without concern being given to the film thickness of the first metal 470 on the side faces of the first resin portions 460. FIG. 31 is a diagram showing an intermediate WLP that is obtained as a result of performing the step 440 from the film formation state in FIG. 30.

In the present embodiment, it is desirable that the width W1 of the opening portions 512 of the metal mask 510 is less than the width W2 of the grooves 462, as shown in FIG. 29. This is because this configuration enables further reducing the film thickness of the first metal 470 on the side faces of the grooves 462.

### Sixth Embodiment

Use of Metal Mask in Step of Forming a Film of First or Second Metal

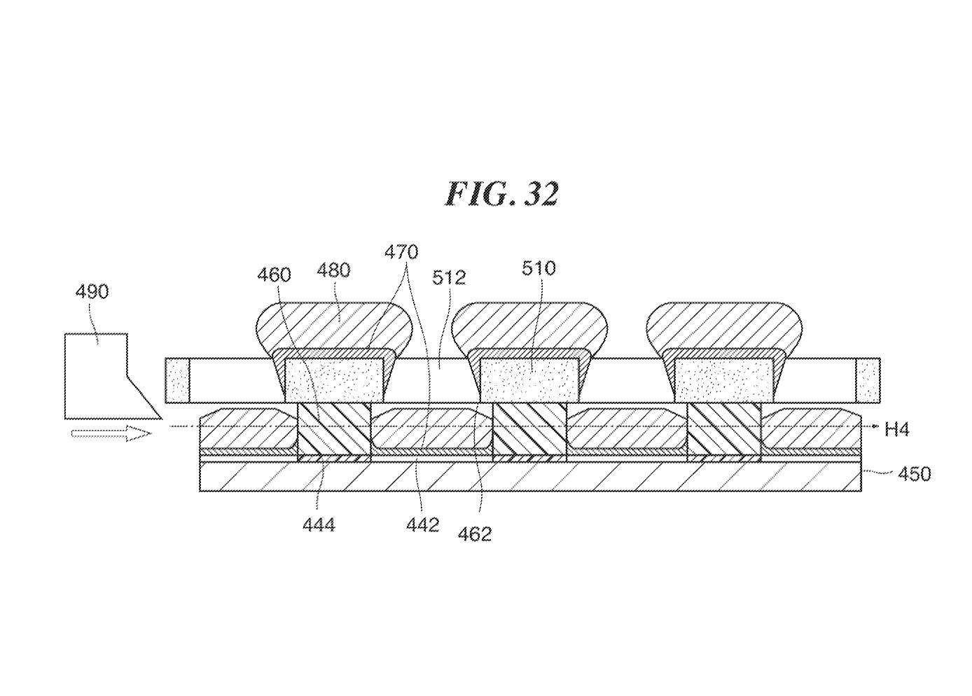

FIG. 32 is a diagram showing a sixth embodiment of the WLP manufacturing method of the present invention. In the present embodiment as well, in the step 400 of FIG. 17, similarly to the second embodiment, the grooves 462 are formed such that the first resin portions 460 of a rectangular cross section remain. Thereafter, the steps 410 and 420 are performed using the metal mask 510 including opening portions 512 at positions corresponding to the grooves 462. The setting and lift-off of the metal mask 510 are performed one time each. As a result, as shown in FIG. 32, films of the first and second metal 470 and 480 are formed in the grooves 462 and on portions of the metal mask 510 positioned over the first resin portions 460.

When the metal mask 510 is lifted off from the film formation state in FIG. 32, films of the first and second metal 470 and 480 are formed only in the grooves 462. Accordingly, in the present embodiment as well, similarly to the fifth embodiment, in the step 440, cutting can be performed along the cutting line at the height H4 where the first metal 470 is not present, without concern being given to the film thickness of the first metal 470 on the side faces of the first resin portions 460.

A diagram showing an intermediate WLP that is obtained as a result of performing the step 440 from the film formation state in FIG. 32 would be the same as the above-described FIG. 31.

In the present embodiment as well, the film of second metal may be formed using a sputtering method or a plating method. This is because there is little influence on the wearing of the cutter and the like even when the film thickness of the second metal, which has a relatively low hardness, is high.

Substrates of First to Sixth Embodiments

The substrate 450 in the above embodiments is envisioned to be a semiconductor substrate (e.g., a silicon wafer) including circuits and internal terminal electrodes for the input and output of signals with the circuits. In other words, it is the wafer before dicing into respective chips is performed.

The completed WLP according to the first embodiment shown in FIG. 1 is used as a representative example of the fan-in type. Since the substrate 1 is a silicon wafer as described above, the wiring 21 formed as a film in the grooves forms a wiring layer (re-wiring layer) that is connected to the internal terminal electrodes 2 and the external terminal electrodes 9 provided as the fan-ins in the region corresponding to the chips of the semiconductor substrate 1.

### Seventh Embodiment

Fan-Out WLP Substrate

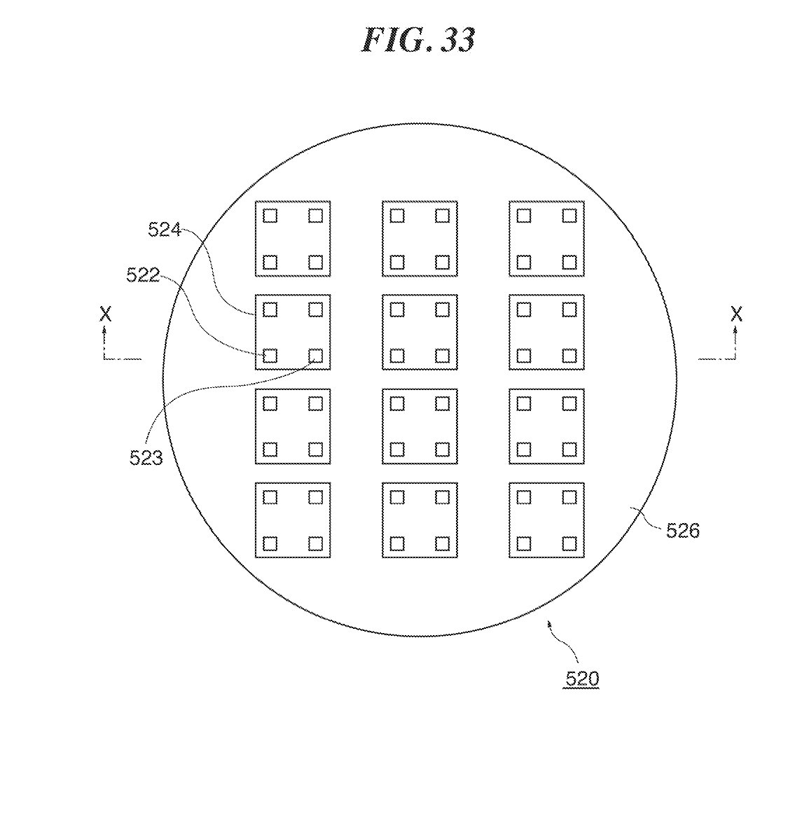

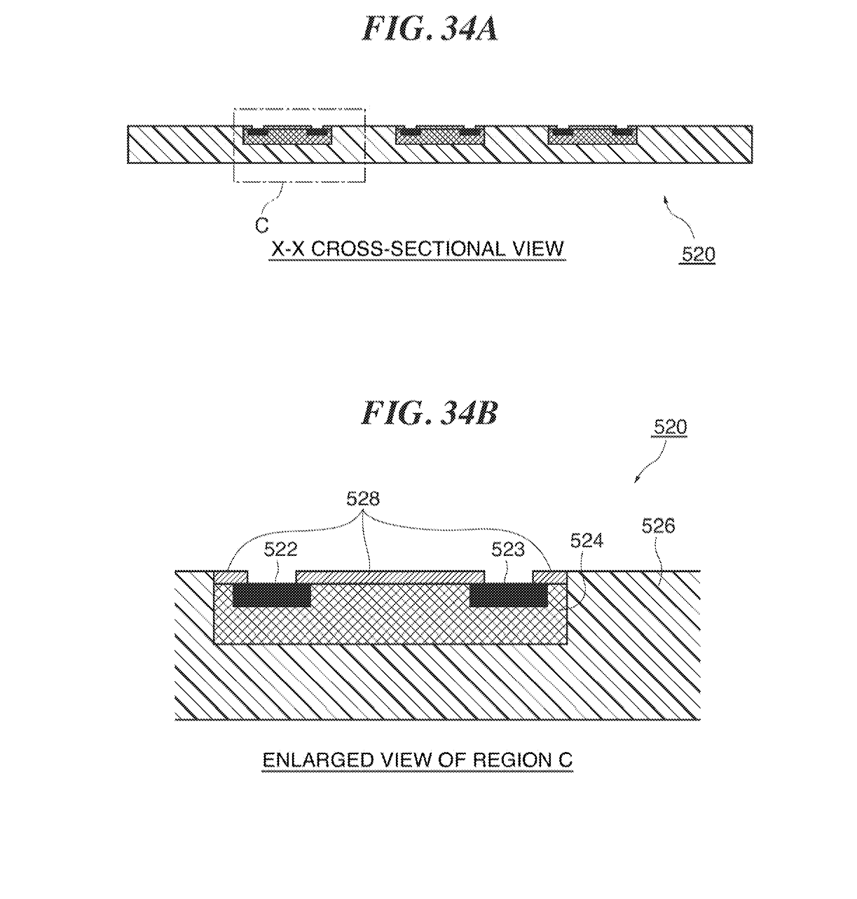

FIG. 33 is a diagram illustrating a seventh embodiment of the WLP manufacturing method according to the present invention, and is a plan view of the substrate used in this embodiment. FIGS. 34A and 34B are cross-sectional views of FIG. 33. FIG. 34A is a cross-sectional view taken along X-X in FIG. 33, and FIG. 34B is an enlarged view of region C in FIG. 34A. In the present embodiment, unlike the first to sixth embodiments, the WLP manufacturing method shown in FIG. 17 is applied to a fan-out WLP substrate 520 instead of the simple semiconductor substrate 450 (silicon wafer).

As shown in FIGS. 34A and 34B, the fan out WLP substrate 520 includes semiconductor chips 524 that each include circuits (not shown) and internal terminal electrodes 522 and 523 for the input and output of signals with the circuits, and also insulating second resin 526 (sealing resin) that covers at least the side faces of the semiconductor chips 524. The internal terminal electrode 522 and 523 may be aluminum pads.

A passivation film 528 is provided over the top face of each semiconductor chip 524 in a region excluding the internal terminal electrodes 522 and 523, and the internal terminal electrodes 522 and 523 are exposed. The passivation film 528 may be polyimide resin, silicon nitride, silicon oxide, or the like.

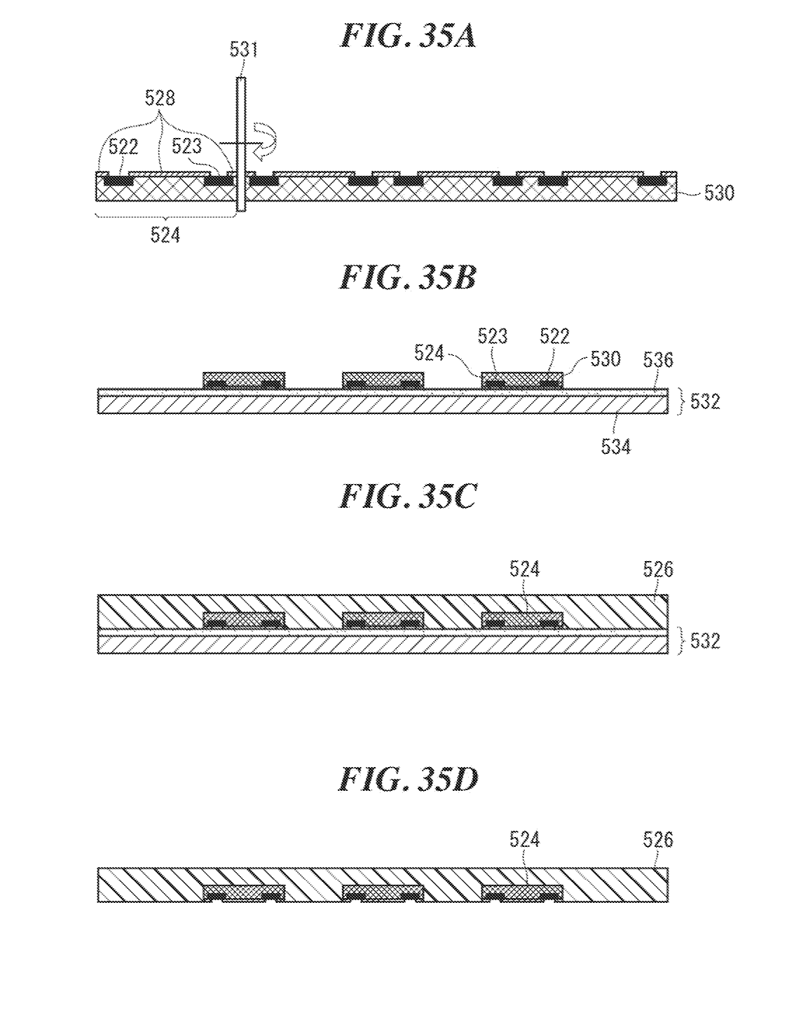

FIGS. 35A to 35D are diagrams illustrating an example of steps for manufacturing the fan-out WLP substrate 520 in FIG. 33. First, as shown in FIG. 35A, an abrasive 531 is used to dice individual chips away from the semiconductor wafer 530 whose top face comprises the internal terminal electrodes and the passivation film provided thereon.

Next, as shown in FIG. 35B, the internal terminal electrodes 522 and 523 sides of the separated semiconductor chips 524 are aligned face-down with the other chips on chip fixing tape 532. The chip fixing tape 532 is made of a base 534 and an adhesive layer 536 that form a laminate, and the semiconductor chips 524 are fixed by the adhesive layer 536.

Next, as shown in FIG. 35C, the semiconductor chips 524 are sealed with the insulating second resin 526, and then as shown in FIG. 35D, the chip fixing tape 532 is peeled off. This completes the manufacture of the fan-out WLP substrate 520 shown in FIGS. 33 and 34.

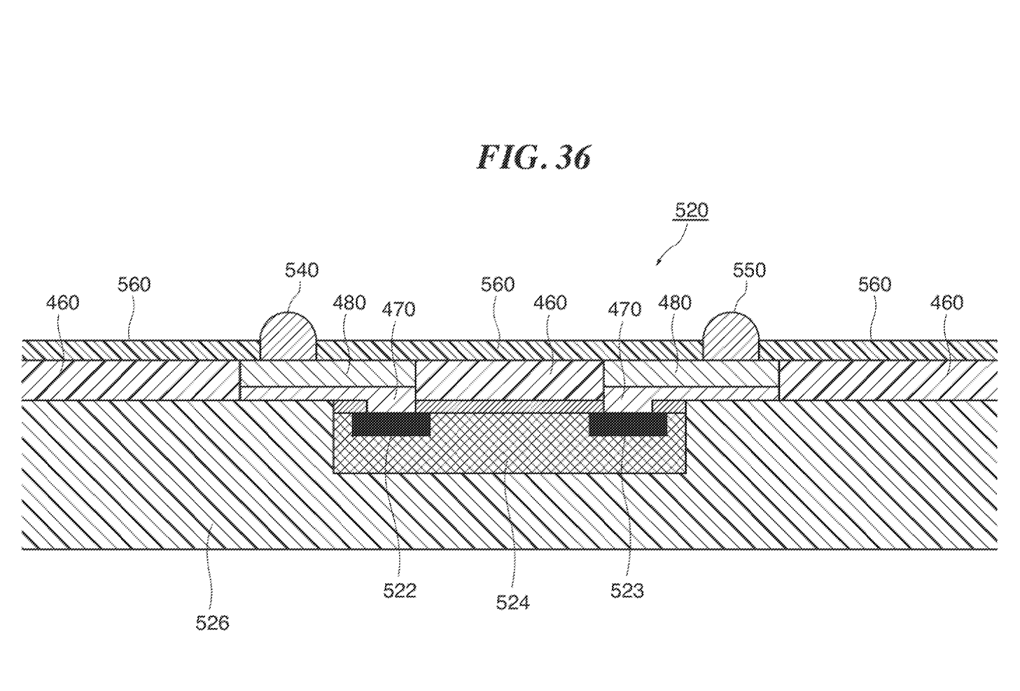

FIG. 36 is a diagram illustrating part of an example of a completed WLP that was manufactured by applying the WLP manufacturing method shown in FIG. 17 to the fan-out WLP substrate 520 in FIG. 33. The films of the first metal 470 and the second metal 480 that were formed in the grooves form a wiring layer that is connected to the internal terminal electrodes 522 and 523, and to external terminal electrodes (e.g., solder balls) 540 and 550 that are provided as fan-outs in the second resin 526 outside the region of the semiconductor chip 524. A film of insulating solder resist 560 is formed surrounding the external terminal electrodes 540 and 550.

As described above, in all of the embodiments of the present invention, “substrate” is not limited to a semiconductor substrate, and also includes a glass substrate and a substrate made of another material (organic or inorganic). Meanwhile, “semiconductor substrate” refers in some cases to a silicon wafer, and in other cases to a fan-out WLP substrate as in the seventh embodiment.

Supplementary Remarks

The following are supplementary remarks disclosing a semiconductor device of the present invention.

(1: FIG. 19)

A semiconductor device includes a semiconductor substrate 450, an insulating first resin layer 460 that is formed over the top face of the semiconductor substrate 450 and includes a groove 462 in which wiring is formed, and a metal layer formed in the groove 462 as the wiring, wherein a main component of the first resin layer 460 is phenol resin, unsaturated polyester resin, melamine resin, or urea resin.

(2: FIG. 19)

The semiconductor device according to supplementary remark 1, wherein the semiconductor substrate 450 comprises a passivation film 444 on at least a portion of the top face thereof, and the passivation film 444 is in contact with the first resin layer 460.

(3: FIG. 19)

The semiconductor device according to supplementary remark 2, wherein a main component of the passivation film 444 is polyimide resin.

(4: FIG. 19)

The semiconductor device according to supplementary remark 3, wherein the first resin layer 460 is a resin that adheres to the polyimide resin.

(5: FIG. 19)

The semiconductor device according to supplementary remark 4, wherein the first resin layer 460 is a photosensitive resin.

(6: FIG. 19)

The semiconductor device according to any one of supplementary remarks 1 to 5, wherein the metal layer includes a first metal 470 that is a barrier metal and a second metal 480 that is Cu or Al.

(7: FIG. 19)

The semiconductor device according to supplementary remark 6, wherein the first metal 470 is Ti, Cr, Ta, or Pd.

(8: FIG. 19)

The semiconductor device according to any one of supplementary remarks 1 to 7, wherein a cross section of the first resin layer 460 is rectangular, positive tapered, or inverse tapered with respect to the top face of the semiconductor substrate 450.

(9: FIG. 1)

The semiconductor device according to any one of supplementary remarks 1 to 3, wherein the semiconductor substrate 1 further includes a circuit, an internal terminal electrode 2 for input and output of a signal with the circuit, and an external terminal electrode 9 provided as a fan-in in a region corresponding to a chip of the semiconductor substrate 1, wherein the wiring is connected to the internal terminal electrode 2 and the external terminal electrode 9.

(10: FIG. 36)

The semiconductor device according to any one of supplementary remarks 1 to 3, wherein the semiconductor substrate 520 further includes a semiconductor chip 524 in which a circuit and internal terminal electrodes 522 and 523 for input and output of a signal with the circuit are included, an insulating second resin layer 526 that covers at least a side face of the semiconductor chip 524, and external terminal electrodes (solder balls) 540 and 550 provided as fan-outs in the second resin layer 526 outside the region of the semiconductor chip 524, wherein the first resin layer 460 is formed on the semiconductor chip 524 and the top face of the second resin layer 526 outside the region of the chip 524, and the wiring (first metal (e.g., Ti) 470 and second metal (e.g., Cu) 480) is connected to the internal terminal electrodes 522 and 523 and the external terminal electrodes 540 and 550.

The present invention is applicable to, for example, a method for manufacturing a wafer level package.

What is claimed is:

1. A method for manufacturing a wafer level package comprising:
forming insulating first resin over a top face of a substrate, the first resin including a groove in which wiring is to be formed;
forming a film of first metal that is to serve as a portion of the wiring on a top face of the first resin using physical vapor deposition;
forming a film of second metal that is to form a portion of the wiring on a top face of the first metal, the second metal of a lower hardness than that of the first metal;
setting a cutter at a height at which the film of the first metal is not formed on a side face of the groove; and
cutting at least the first resin by scanning the cutter.

2. A method for manufacturing a wafer level package comprising:
forming insulating first resin on a top face of a substrate, the first resin including a groove in which wiring is to be formed;
forming a film of first metal that is to serve as a portion of the wiring on a top face of the first resin using physical vapor deposition;
forming a film of second metal that is to form a portion of the wiring on a top face of the first metal, the second metal having a lower hardness than that of the first metal;
setting a cutter at a height at which the film of the first metal is not formed on a side face of the groove, or at a height corresponding to a place where the thickness of the film of the first metal formed on the side face of the groove is lower than the thickness of the film of the first metal formed on an upper face of the first resin or lower than the thickness of the film of the first metal formed on a bottom face of the groove; and
cutting at least the first resin by scanning the cutter,
wherein a main component of the first resin is phenol resin, unsaturated polyester resin, melamine resin, or urea resin.

3. The method for manufacturing a wafer level package according to claim 2,
wherein the substrate has a passivation film on at least a portion of the top face thereof, and the passivation film is in contact with the first resin.

4. The method for manufacturing a wafer level package according to claim 3,
wherein a main component of the passivation film is polyimide resin.

5. A method for manufacturing a wafer level package comprising:
forming insulating first resin over a top face of a substrate, the first resin including a groove in which wiring is to be formed;
forming a film of first metal that is to serve as a portion of the wiring on a top face of the first resin using physical vapor deposition;
forming a film of second metal that is to form a portion of the wiring on a top face of the first metal, the second metal of a lower hardness than that of the first metal;
setting a cutter at a height at which the film of the first metal is not formed on a side face of the groove, or at a height corresponding to a place where the thickness of the film of the first metal formed on the side face of the groove is lower than the thickness of the film of the first metal formed on an upper face of the first resin or lower than the thickness of the film of the first metal formed on a bottom face of the groove; and
cutting at least the first resin by scanning the cutter,
wherein the film of first metal is formed using an ion plating method that employs a metal mask including an opening portion at a position corresponding to the groove.

6. The method for manufacturing a wafer level package according to claim 2,
wherein the film of second metal is formed using physical vapor deposition.

7. The method for manufacturing a wafer level package according to claim 6,
wherein the film of second metal is formed using an ion plating method that employs a metal mask including an opening portion at a position corresponding to the groove.

8. The method for manufacturing a wafer level package according to claim 6,
wherein the film of second metal is formed using a sputtering method.

9. The method for manufacturing a wafer level package according to claim 2,
wherein the film of second metal is formed using a plating method.

10. The method for manufacturing a wafer level package according to claim 5,
wherein the first resin is formed such that a cross section of the first resin adjacent to the groove is rectangular or positive tapered with respect to the top face of the substrate.

11. The method for manufacturing a wafer level package according to claim 5,
wherein the width of the opening portion is less than the width of the groove.

12. A method for manufacturing a wafer level package comprising:
forming insulating first resin over a top face of a substrate, the first resin including a groove in which wiring is to be formed;
forming a film of first metal that is to serve as a portion of the wiring on a top face of the first resin using physical vapor deposition;
forming a film of second metal that is to form a portion of the wiring on a top face of the first metal, the second metal of a lower hardness than that of the first metal;
setting a cutter at a height at which the film of the first metal is not formed on a side face of the groove, or at a height corresponding to a place where the thickness of the film of the first metal formed on the side face of the groove is lower than the thickness of the film of the first metal formed on an upper face of the first resin or lower than the thickness of the film of the first metal formed on a bottom face of the groove; and
cutting at least the first resin by scanning the cutter,
wherein the first resin is formed such that a cross section of the first resin adjacent to the groove is inverse tapered with respect to the top face of the substrate.

13. The method for manufacturing a wafer level package according to claim 12,
wherein the film of first metal is formed using a sputtering method or an ion plating method.

14. The method for manufacturing a wafer level package according to claim 12,
wherein the film of second metal is formed using physical vapor deposition.

15. The method for manufacturing a wafer level package according to claim 12,
wherein the film of second metal is formed using a plating method.

16. The method for manufacturing a wafer level package according to claim 14,
wherein the film of second metal is formed using a sputtering method or an ion plating method.

17. The method for manufacturing a wafer level package according to claim 2,
wherein the second metal is cut along with the first resin by scanning the cutter.

18. The method for manufacturing a wafer level package according to claim 2,
wherein the first metal whose thickness is less than the thickness of the film of the first metal formed on the upper face of the first resin or on the bottom face of the groove is cut along with the first resin by scanning the cutter.

19. The method for manufacturing a wafer level package according to claim 2,
wherein the substrate is a semiconductor substrate including a circuit and an internal terminal electrode for input and output of a signal with the circuit, and
the film of the first metal and the film of the second metal formed in the groove form a wiring layer that is connected to the internal terminal electrode and an external terminal electrode provided as a fan-in in a region corresponding to a chip of the semiconductor substrate.

20. The method for manufacturing a wafer level package according to claim 2,
wherein the substrate includes a semiconductor chip in which a circuit and an internal terminal electrode for input and output of a signal with the circuit are included, and insulating second resin that covers at least a side face of the semiconductor chip, and
the film of the first metal and the film of the second metal formed in the groove form a wiring layer that is connected to the internal terminal electrode and an external terminal electrode provided as a fan-out in the second resin outside a region of the semiconductor chip.

21. A method for manufacturing a wafer level package comprising:
forming insulating first resin over a top face of a substrate, the first resin including a groove in which wiring is to be formed;
forming a film of a first metal that is to serve as a portion of the wiring on a top face of the first resin using physical vapor deposition;
forming a film of second metal that is to form a portion of the wiring on a top face of the first metal, the second metal of a lower hardness than that of the first metal;
setting a cutter at a height corresponding to a low-thickness portion of the first metal whose film thickness varies on the side face of the groove, the low-thickness portion having a thickness lower than the thickness of the film of the first metal formed on an upper face of the first resin or than the thickness of the film of the first metal formed on a bottom face of the groove; and
cutting at least the first resin by scanning the cutter.

22. The method for manufacturing a wafer level package according to claim 1,
wherein a main component of the first resin is phenol resin, unsaturated polyester resin, melamine resin, or urea resin.

23. The method for manufacturing a wafer level package according to claim 22,
wherein the substrate comprises a passivation film on at least a portion of the top face thereof, and the passivation film is in contact with the first resin.

24. The method for manufacturing a wafer level package according to claim 23,
wherein a main component of the passivation film is polyimide resin.

25. The method for manufacturing a wafer level package according to claim 21,
wherein the film of first metal is formed using an ion plating method that employs a metal mask including an opening portion at a position corresponding to the groove.

26. The method for manufacturing a wafer level package according to any one of claim 21,
wherein the film of second metal is formed using physical vapor deposition.

27. The method for manufacturing a wafer level package according to claim 26,
wherein the film of second metal is formed using an ion plating method that employs a metal mask including an opening portion at a position corresponding to the groove.

28. The method for manufacturing a wafer level package according to claim 26,
wherein the film of second metal is formed using a sputtering method.

29. The method for manufacturing a wafer level package according to any one of claim 21,
wherein the film of second metal is formed using a plating method.

30. The method for manufacturing a wafer level package according to claim 25,
wherein the first resin is formed such that a cross section of the first resin adjacent to the groove is rectangular or positive tapered with respect to the top face of the substrate.

31. The method for manufacturing a wafer level package according to claim 25,
wherein the width of the opening portion is less than the width of the groove.

32. The method for manufacturing a wafer level package according to any one of claim 21,
wherein the first resin is formed such that a cross section of the first resin adjacent to the groove is inverse tapered with respect to the top face of the substrate.

33. The method for manufacturing a wafer level package according to claim 32,
wherein the film of first metal is formed using a sputtering method or an ion plating method.

34. The method for manufacturing a wafer level package according to claim 32,
wherein the film of second metal is formed using physical vapor deposition.

35. The method for manufacturing a wafer level package according to claim 32,
wherein the film of second metal is formed using a plating method.

36. The method for manufacturing a wafer level package according to claim 34,
wherein the film of second metal is formed using a sputtering method or an ion plating method.

37. The method for manufacturing a wafer level package according to claims 1,
wherein the second metal is cut along with the first resin by scanning the cutter.

38. The method for manufacturing a wafer level package according to claim 1,
wherein the substrate is a semiconductor substrate including a circuit and an internal terminal electrode for input and output of a signal with the circuit, and
the film of the first metal and the film of the second metal formed in the groove form a wiring layer that is connected to the internal terminal electrode and an external terminal electrode provided as a fan-in in a region corresponding to a chip of the semiconductor substrate.

39. The method for manufacturing a wafer level package according to claim 1,
wherein the substrate includes a semiconductor chip in which a circuit and an internal terminal electrode for input and output of a signal with the circuit are included, and insulating second resin that covers at least a side face of the semiconductor chip, and
the film of the first metal and the film of the second metal formed in the groove form a wiring layer that is connected to the internal terminal electrode and an external terminal electrode provided as a fan-out in the second resin outside a region of the semiconductor chip.

40. The method for manufacturing a wafer level package according to claim 1,
wherein the tensile strength of the first resin is less than or equal to 80 Mpa (eighty Mega pascal).

41. The method for manufacturing a wafer level package according to claim 40,
wherein a main component of the first resin is phenol resin.

42. The method for manufacturing a wafer level package according to claim 1,
wherein the first resin is formed such that a cross section of the first resin adjacent to the groove is rectangular or positive tapered with respect to the top face of the substrate.

43. The method for manufacturing a wafer level package according to claim 42,
wherein a main component of the first resin is phenol resin, unsaturated polyester resin, melamine resin, or urea resin.

44. The method for manufacturing a wafer level package according to claim 43,
wherein the substrate comprises a passivation film on at least a portion of the top face thereof, and the passivation film is in contact with the first resin.
